(19) United States
(12) Patent Application Publication
(10) Pub. No.: US 2001/0054435 A1
(43) Pub. Date: Dec. 27, 2001

(54) Facing material, fabricating method thereof, solar cell module, manufacturing method thereof, installing method thereof, and photovoltaic power-generating apparatus

(76) Inventors: Yoshitaka Nagao, Soraku-gun (JP); Akiharu Takabayashi, Nara-shi (JP)

Correspondence Address: FITZPATRICK CELLA HARPER & SCINTO, 30 ROCKEFELLER PLAZA, NEW YORK, NY, 10112, US

(21) Appl. No.: 09/824,092

(22) Filed: Apr. 3, 2001

(30) Foreign Application Priority Data
Apr. 4, 2000 (JP) 2000-101916
Apr. 4, 2000 (JP) 2000-101917
Apr. 4, 2000 (JP) 2000-101918
Mar. 30, 2001 (JP) 2001-100013

(51) Int. Cl. H01L 21/00; B32B 5/02

(52) U.S. Cl. 136/251; 136/244; 438/64; 442/136; 442/164; 442/85; 427/385.5

(57) ABSTRACT

The facing material of the present invention comprises fire resistive fibers and is formed by integrating a waterproofing layer which is the fire resistive fibers impregnated with a filler with a fire resistive layer which is the fire resistive fibers not impregnated with the filler, thereby providing a facing material of a roofing material and the like, realizing high productivity, high installability, waterproof performance, and a light weight, without a structural load on a building, having a high fire protective performance and a manufacturing method thereof, a construction and an installing method thereof, and a photovoltaic power-generating apparatus.

### BACKGROUND OF THE INVENTION

1. Field of the Invention

The present invention relates to a facing material such as a roofing material, a fabricating apparatus, a fabricating method, and an installing method for the facing material, and a building, and a photovoltaic power-generating apparatus.

The present invention relates to a solar cell module produced by sealing a photovoltaic element with a filler, a manufacturing method thereof, a manufacturing apparatus thereof, and an installing method thereof, a building equipped with a solar cell, and a photovoltaic power-generating apparatus.

2. Related Background Art

Recently, as a roofing material to minimize damage by earthquake and have an advantage in structural calculation, the roofing material of a light weight or the roofing material good in installing performance and having a large area has been developed. Among them, a slate roofing material consisting of an asbestos cement plate is frequently used for a roof of a living house. In addition, in a case of a concrete-made roof substrate, asphalt single, which is formed by impregnating a felt-like core material with asphalt and attaching colored sand to its surface, and a waterproofing sheet are frequently used.

However, asbestos used in the former is a substance adversely affecting a human body and is fragile.

On the other hand, it has been known that the asphalt single and the like has flexibility to prevent break, however, is easy to burn in fire and thus has a defect in fire protection. To use for the roofing material of a building, a special consideration is needed for fire protection and fireproof of the building. Particularly, a performance to prevent the spread of fire is required in consideration of leaping from neighboring fire.

To solve these problems, in Japanese Patent Publication No. 4-74470, an incombustible single, which is produced by impregnating a fire retardant filler in a fiber sheet and attaching a mineral granular powder to its surface to give weather resistance, has been proposed.

In Japanese Patent Application Laid-Open No. 5-331753, an example of a construction material having flame resistive performance has been proposed. This is prepared by adhesion of flame resistive fibers to a substrate and requires another substrate to keep performances such as waterproof and hence, a weight increases according to increase in a used quantity of the substrate. In the case where the substrate is combustible, a disadvantage occurs in aspect of the spread of fire of the surface. In addition, as proposed herewith, in the case where an adhesive is impregnated after the flame resistive fibers are stacked on the substrate, flame resistivity may be influenced badly.

Further, in the case where the solar cell module is installed on a roof and the like, a plurality of the solar cell modules are used. Particularly, in the case where the solar cell modules are used as the roofing material, it is necessary that portions where the solar cell modules overlap are provided to keep waterproof. In this case, enough fire protection performance should be kept also in the portions where the solar cell modules overlap.

By the way, in recent years, global warming, fossil fuel exhaust, atomic power plant accident, and radioactive pollution by a radioactive waste are become problems and public concern has rapidly intensified about global environment and energy. Under such situation, a solar energy collection apparatus such as the solar cell is expected for an exhaustless and clean energy source. Particularly, the solar cell installable on the roof of the living house has been proposed and its use has been spread.

As a form of installation of the solar cell on the roof of the building and the like, the followings have been proposed: a method for installing a trestle and a fixing member on an existing roof to fix a solar cell panel thereon, and a method for integrating a photovoltaic element with a tile and a metal roof and installing it on a sheathing roof board as the roofing material.

However, in order to use as the roofing material of buildings, fire protection and fireproof performance of buildings should be considered. Particularly, a performance to prevent spreading of fire is required in consideration of leaping from neighboring fire. Therefore, in Japanese Patent Application Laid-Open No. 8-302942 the method for installing a metal board with a distance from the solar cell body under a bottom face side of a conventional solar cell panel has been proposed. However, for this method, there is a step for installation of the metal board in the step of producing the solar cell module, a productivity is low, and special processing is required for a frame body of the solar cell panel to increase a cost. In addition, a steel plate or inorganic heavy member should be used on a back face of the solar cell, and therefore productivity and installing performance are low. Besides, the module having glass as the surface material is particularly heavy to have disadvantages in structure calculation of buildings and influences an earthquake-proof performance. Furthermore, when using a punching metal, a melted resin falls down from a hole thereof to make firing of a combustible resin installed inside the roofing material possible.

In Japanese Patent Application Laid-Open No. 9-69646, a proposal has been made for the solar cell module, in which a network body impregnated with an adhesive resin in a portion either between the photovoltaic element and a transparent board or a portion between the photovoltaic element and a back cover or both portions of them has been installed. However, the adhesive resin is impregnated in the network body and hence, even if the network body is made of inorganic fibers, the adhesive resin impregnated in the back face and the back cover resin are fired to disturb a satisfactory fire protection performance. Therefore, a fire retardant should be composed in the resin material itself. In this case, a problem may occur in a long period reliability of weather resistivity of the resin itself.

In U.S. Pat. No. 5437735, one, in which fibers are contained in an organic resin of the solar cell roofing material, has been defined; however, it has no layer made up with only fibers.

### SUMMARY OF THE INVENTION

The present first and second objects, in consideration of the above-described problems, are to provide a facing material such as the roofing material having a high fire protection performance without a structural load on a building by using fibers having flame resistive performance to make a configuration comprising a waterproofing layer and flame resistive layer in a flame resistive fiber by realizing a high productivity, installability, and waterproof performance and a light weight; a solar cell module; a manufacturing apparatus for the facing material; a manufacturing apparatus, a manufacturing method and a installing method for the solar cell module; a building; and a photovoltaic power-generating apparatus.

For accomplishing the first object, an aspect of the present invention is to provide a facing material comprising at least flame resistive fibers and a filler, wherein the facing material has a waterproofing layer comprising the flame resistive fibers impregnated with the filler and a flame resistive layer comprising the flame resistive fibers not impregnated with the filler and wherein the flame resistive layer is provided on the surface of the facing material.

An aspect of the present invention is to provide a fabricating apparatus for the above-described facing material, comprising a degassing means and a heating means, wherein a stacked body comprising a covering means composed of flame resistive fibers and a sheet member of a thermoplastic resin is heated while degassing a space between the covering means and the sheet member, and the fibers and the sheet member are closely attached and fixed to each other.

An aspect of the present invention is to provide a fabricating apparatus for the above-described facing material, comprising a pressing means and a heating means, wherein a stacked body comprising a covering means composed of flame resistive fibers and a thermoplastic resin is heated and pressed to closely attach and fix the fibers and the resin to each other.

An aspect of the present invention is to provide a fabricating method for the above-described facing material, wherein a covering means composed of flame resistive fibers and a sheet member of a thermoplastic resin are stacked, heated while degassing a space between the covering means and the sheet member of the thermoplastic resin, and closely attached and fixed to each other.

An aspect of the present invention is to provide a fabricating method for the above-described facing material, wherein a covering means composed of flame resistive fibers and a thermoplastic resin are arranged, and hot-pressed to closely attach and fix the covering means and the resin to each other.

An aspect of the present invention is to provide a method for installing a facing material by fixing the facing material to a roof substrate and an external wall with a fixing member, wherein the facing material is the above-described facing material.

An aspect of the present invention is to provide a building in which the above-described facing material is fixed to a roof substrate or an external wall by the fixing member.

An aspect of the present invention is to provide a photovoltaic power-generating apparatus, in which the above-described facing material is installed in a portion, of a plane having a solar cell module, where the module is not arranged.

An aspect of the present invention is to provide a method for keeping a facing material, comprising transporting or keeping the above-described facing material in a condition of winding in a length direction of the facing material.

An aspect of the present invention is to provide a method for keeping a facing material, comprising transporting or keeping the above-described facing material in a condition of stacking in the same direction.

For accomplishing the second object, an aspect of the present invention is to provide a solar cell module comprising a photovoltaic element and a covering means comprising a flame resistive fiber, arranged in a non-light-receiving face side of the photovoltaic element, wherein the above-described solar cell module has a flame resistive layer on the surface of the non-light-receiving face side of the above-described solar cell module and has a water-absorption preventing layer on the surface of the flame resistive layer.

An aspect of the present invention is to provide a method for keeping a solar cell module, comprising transporting or keeping in a condition of winding in a length direction thereof.

An aspect of the present invention is to provide a method for keeping a solar cell module, comprising transporting or keeping in a condition of stacking in the same direction.

An aspect of the present invention is to provide a method for fabricating the above-described solar cell module comprising a photovoltaic element and a covering means comprising a flame resistive fiber, arranged in a non-light-receiving face side of the photovoltaic element, which comprises arranging a flame resistive layer on the surface of the non-light-receiving face side of the above-described solar cell module and arranging a water-absorption preventing layer on the surface of the flame resistive layer.

A method for installing the solar cell module is provided, which comprises fixing the above-described solar cell module to a trestle, a roof substrate, and an external wall with a fixing member.

A building comprising a solar cell is provided, in which the above-described solar cell module is fixed to a trestle, a roof substrate, and an external wall with a fixing member.

A photovoltaic power-generating apparatus is provided, which comprises the above-described solar cell module and a power conversion apparatus.

According to the aspect of the present invention for the first and second objects, installation of the waterproofing layer in the flame resistive fibers allows keeping a waterproof performance with a quantity of the filler reduced. In a product prepared by adhesion of the flame resistive fibers to a base member with the adhesive, a sheet member such as of an organic compound should be used as a base member in order to keep the waterproof performance and the like. In comparison with this case, in the formed of the present invention, a waterproofing layer is formed by using the flame resistive fibers together with the fillers. Thus, the quantity of combustible organic compound can be reduced to increase a performance of the surface to prevent spreading of fire. In addition, in comparison with the case where an adhesive is impregnated after the flame resistive fibers are stacked, in the configuration of the present invention, the quantity of the organic compound can be reduced and the layer made of only the flame resistive fibers is prominently increased in the fire protection performance.

By using the flame resistive fibers comprising the waterproofing layer and the flame resistive layer, break caused by a flanker of fire does not occur and a flame does not contact directly to the roof substrate face to prevent the roof substrate face from catching fire and even if the resin of the surface melts, a capillary phenomenon of the fibers can prevent the resin melted from falling down. Particularly, the flame resistive layer, which is not impregnated with the filler in the back face, has been installed and thus, the fire protection performance is higher. Further, it is made of the fibrous material and therefore, it is light in weight in comparison with such material as the steel plate and the tile, a production site and an installing person receives a less burden, an assumed load for the building becomes small to make structure calculation advantageous, and realizes reduction of costs of structural members of construction. Furthermore, the roofing material can be arranged on the roof substrate and therefore, a space configured by the roofing material and the roof substrate face does not almost occur and hence, oxygen supply is reduced to improve the fire protection performance of the roof.

The portion made by overlapping the facing materials can keep enough waterproof performance by the fact that the fibers have the water-absorption preventing layer, which prevents partial projection of the fibers to the surface. In addition, in the case where a resin or the like is used in a surface protective layer, the surface protective layer is not provided in the overlapped portion, thereby reducing the quantity of the used resin to improve the fire protection performance.

Further, the fibers arranged on the surface allows the facing material to take a role of a packaging material in keeping and transporting in stacked state and thus, injury is difficult to occur and the quantity of the packing material can be reduced.

The portion made by overlapping the solar cell modules can keep enough waterproof performance by the fact that the fibers have the water-absorption preventing layer, which prevents partial projection of the fibers to the surface. In addition, in the case where a resin or the like is used for a surface protective layer and an insulation layer, the surface protective layer or the insulation layer in the overlapped portion is not provided, thereby reducing the quantity of the used resin to improve the fire protection performance.

Further, the fibers arranged on the surface allows the facing material to take a role of a packaging material in keeping and transporting in stacked state and thus, injury is difficult to occur and the quantity of the packing material can be reduced.

In consideration of the above-described problems, the third object of the present invention is to provide a solar cell module without a structural load on the building and with a high productivity, installability, and a light weight; a manufacturing method thereof; a manufacturing apparatus thereof; and an installing method thereof; a building; and a photovoltaic power-generating apparatus.

For accomplishing the third object, an aspect of the present invention is to provide a solar cell module comprising a photovoltaic element sealed with a filler, wherein a covering means containing a layer having flame resistive performance which is made of flame resistive fibers on the non-light-receiving face of the above-described photovoltaic element.

An aspect of the present invention is to provide a manufacturing method for a solar cell module, in which a covering means made of flame resistive fibers, a sheet member of a thermoplastic resin, and a photovoltaic element are stacked, heated while degassing a space between the covering means and the sheet member of the thermoplastic resin and a space between the sheet member of the thermoplastic resin and the photovoltaic element and closely attached and fixed to each other.

An aspect of the present invention is to provide a manufacturing method for a solar cell module, in which any one of an adhesive material or a sticky material is applied to a covering means made of flame resistive fibers, the applied covering means and a photovoltaic element are stacked, and a portion between the covering means and the photovoltaic element is pressed to closely attach and fix them to each other.

An aspect of the present invention is to provide a manufacturing apparatus for a solar cell module having a degassing means and a heating means, wherein a covering means made of flame resistive fibers, a sheet member of a thermoplastic resin, and the photovoltaic element are stacked and heated while degassing a space between the covering means and the sheet member of the thermoplastic resin and a space between the sheet member of the thermoplastic resin and the photovoltaic element.

An aspect of the present invention is to provide a manufacturing apparatus for a solar cell module comprising an applying means for applying any one of a adhesive material or a sticky material as a filler to a covering means made of flame resistive fibers, and a heating means, wherein a photovoltaic element and the covering means are stacked, and a portion between the covering means and the photovoltaic element is pressed to closely attach and fix them to each other.

An aspect of the present invention is to provide a method for installing the solar cell module, wherein the above-described solar cell module is fixed to a trestle, a roof substrate, and an external wall with a fixing member.

An aspect of the present invention is to provide a building comprising the solar cell, wherein the above-described solar cell module is fixed to a trestle, a roof substrate, and an external wall with a fixing member.

An aspect of the present invention is to provide a photovoltaic power-generating apparatus, comprising the above-described solar cell module and the power conversion apparatus.

According to the aspects of the present invention for the third object, a covering means is made of the fibers having flame resistive performance and therefore, break caused by a flanker of fire does not occur and a flame does not contact directly to the roof substrate face to prevent the roof substrate face from catching fire. Even if the resin of the surface melts, the capillary phenomenon of the fibers forming the layer made of only the fibers can prevent the melted resin from falling down. Particularly, in the case where the filler is not impregnated in the back face, the fire protection performance is higher. Further, it is made of the fibrous material and therefore, it is light in weight in comparison with a material such as the steel plate or the tile, the production site and the installing person receives the less burden, the assumed load for the building becomes small to make structure calculation advantageous, and realizes reduction of costs of structural members of construction itself. Furthermore, the solar cell module can be installed on the roof substrate and therefore, the space configured by the solar cell module and the roof substrate face does not almost occur and hence, oxygen supply can be reduced to improve the fire protection performance of the roof.

The solar cell module is fixed to the trestle, the roof substrate and the external wall with the fixing member to produce a construction comprising a solar cell, and the solar cell module and the power conversion apparatus are combined to produce a photovoltaic power-generating apparatus.

Other features and effects in the aspects of the present invention for the first to third objects will be described below in detail with reference to the drawings

### BRIEF DESCRIPTION OF THE DRAWINGS

FIGS. 1A and 1B are schematically cross-sectional views showing a configuration of a facing material of the present invention;

FIG. 2 is a perspective view showing an external appearance of the facing material of the present invention;

FIG. 3 is a schematically cross-sectional view showing the configuration of a roofing material of Example 1;

FIG. 4 is a perspective view showing one example of a jig used for resin sealing of the roofing material of Example 1;

FIG. 5 is a schematic view showing that a filler has been stacked on the jig for resin sealing of the roofing material of Example 1;

FIG. 6 is a perspective view showing one example of a test of fire protection performance;

FIG. 7 is a schematic illustration showing one example of the cross-sectional view of an imitation roof used for the test of fire protection performance using the roofing material of Example 1;

FIG. 8 is a schematical cross-sectional view showing the configuration of the roofing material of Example 2;

FIG. 9 is a schematical cross-sectional view showing the configuration of the roofing material of Example 3;

FIG. 10 is a schematical cross-sectional view showing the configuration of the roofing material of Example 4;

FIG. 11 is a schematic illustration showing a manufacturing situation of the roofing material of Example 4;

FIG. 12A and FIG. 12B are schematic illustrations showing a facing material and one example of installing the facing material;

FIG. 13 is a schematic illustration showing a view of a back face of the facing material;

FIG. 14 is an example of an enlarged view of a part A of FIG. 12A;

FIG. 15 is another example of an enlarged view of a part A of FIG. 12A;

FIG. 16 is a schematically cross-sectional view taken along the line 16-16 of FIG. 17;

FIG. 17 is a perspective view showing a solar cell module of the present invention;

FIG. 18B is a perspective view showing a solar cell module of Example 5, and FIG. 18A is a schematical cross-sectional view taken along the line 18A-18A of FIG. 18B;

FIG. 19B is an illustration viewing from a non-light-receiving face side of the solar cell module of Example 6, and FIG. 19A is a schematical cross-sectional view taken along the line 19A-19A of FIG. 19B;

FIG. 20 is a perspective view showing the status of stacking the solar cell module of Example 6;

FIG. 21 is a schematic view showing one example of the cross-section of the imitation roof used for the test of fire protection performance using the solar cell module of Example 6;

FIG. 22 is a schematic view showing the cross-sectional structure of the solar cell module of Example 7;

FIG. 23 is a schematical cross-sectional view taken along the line 23-23 of FIG. 24;

FIG. 24 is a perspective view showing the solar cell module of the present invention;

FIG. 25 is a diagram showing the cross-sectional structure of the solar cell module of Example 8;

FIG. 26 is a schematic view showing the cross-sectional structure of the solar cell module of Example 9;

FIG. 27 is a perspective view showing the solar cell module of Example 9;

FIG. 28 is a schematic view showing one example of the cross-section of the imitation roof used for the test of fire protection performance using the solar cell module of Example 9;

FIG. 29 is a schematic view showing the cross-sectional structure of the solar cell module of Example 10;

FIG. 30 is a perspective view showing the solar cell module of Example 10;

FIG. 31 is a schematic view showing the cross-sectional structure of the solar cell module of Example 11; and

FIG. 32 is a schematic view showing the cross-sectional structure of the solar cell module of Example 12.

### DESCRIPTION OF THE PREFERRED EMBODIMENTS

A first preferred embodiment of the present invention will be described below. However, the present invention is not restricted by this embodiment.

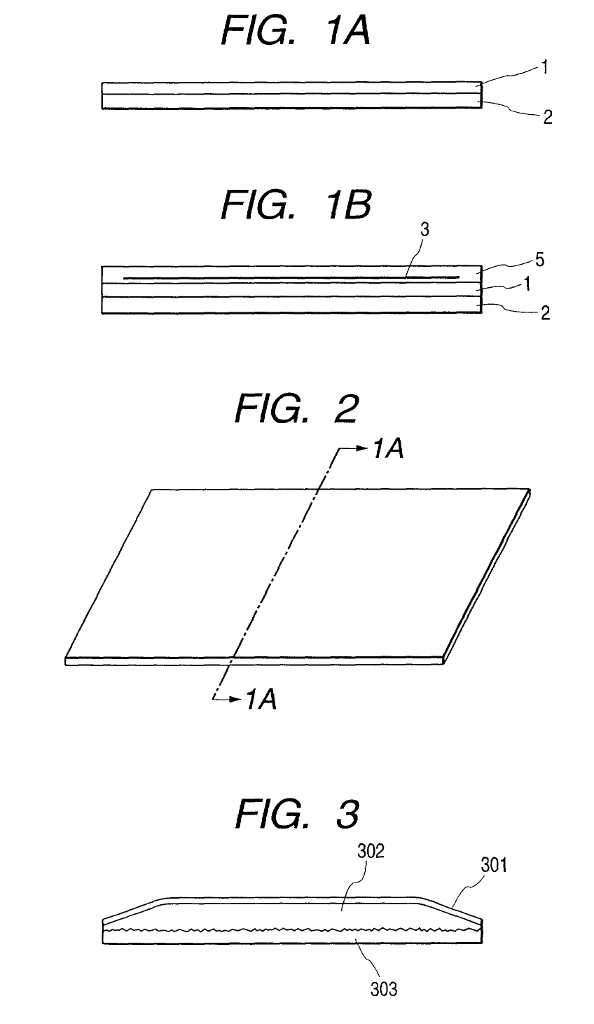

FIG. 2 is a perspective view showing an external appearance of the facing material of the present invention, and FIG. 1A is a cross-sectional view showing the configuration of the facing material of the present invention, taken along the line 1A-1A of the FIG. 2.

The facing material of the present invention has a structure comprising a waterproofing layer 1 and a flame resistive layer 2.

(Flame Resistive Layer)

For the flame resistive layer, fibers having flame resistive performance are used. Here, “having the flame resistive performance” means that one having 26.5 or more of limiting oxygen index (LOI) defined in JIS K7201. Fibers having “a property showing less melting and shrinking degrees, when approaching to flame in air, to keep almost an original shape thereof” or those having incombustibility. For example, those are exemplified by heat resistive and flame resistive fibers such as glass fiber, ceramic fiber, various metal fiber, and metal wire, aramid fiber, novoloid fiber, and polybenzimidazole fiber, flame retardant rayon, flame retardant polyester, flame protective wool, modacrylic fiber, aromatic polyamide, and carbon fiber.

In addition, there are flame resistive fibers and the like yielded by treatment for realizing flame resistivity by a known method using organic fibers such as acrylonitrile-based fiber, rayon fiber, pitch-based fiber, and phenol-based fiber, as a precursor. Among these fibers, flame resistive fibers used as the precursor of the carbon fiber prepared by firing and carbonization of a special acrylic fiber has about 50 of the limiting oxygen index and has no electroconductivity like the carbon fiber, allows cost reduction, and thus, is preferable for flame resistive performance.

As a base member of the facing material or of the covering means of the solar cell module, it is possible to use a sheet-like member which is prepared by processing these fibers so as to produce nonwoven fabric, felt, textile, jersey, or mesh to form a sheet-like shape having voids or irregular portions on at least one surface thereof, and its productivity is good.

Even when a binder is adopted for making the fibers to the sheet in the manufacturing procedure, if the flame resistive performance is maintained, use of the binder is in the range of the present invention. In addition, as described later for the filler of the waterproofing layer, the nonwoven fabric made of glass fibers, in which the resin has been impregnated, does not satisfy a requirement as the base member of the facing material or the covering means of the solar cell module of the present invention, because the resin melts at approaching to the flame.

(Waterproofing Layer)

The waterproofing layer keeps waterproof performance of the construction to protect the roof of the construction. Thus, waterproof performance, weather resistivity, filling performance, heat resistivity, cold resistivity, and shock resistivity are required. As the base member of the waterproofing layer, the flame resistive fibers integrated with the flame resistive layer are used, and as the filler, specifically, ethylene-vinyl acetate copolymer (EVA), ethylene-methyl acrylate copolymer (EMA), ethylene-ethyl acrylate copolymer (EEA), and polyvinyl butylal resin are enumerated. Among these, EVA is the resin frequently used as the filler for the conventional solar cell module, which gives a high reliability, has a function as the adhesive for adhesion to the above-described base member, is low in cost, and thus, EVA is the most preferable material. In addition, two or more kinds of these materials may be used.

(Surface Protective Layer)

In the case where dirt resistivity is necessary, as the surface member of the waterproof means, glass, fluorine resin film and acrylic resin film can be used.

Particularly, in use of the resin film, no break by a shock from outside occurs. In addition, the resin film is the material of which weight is very light than glass and hence, the weight of the facing material or the solar cell module can be reduced. In other words, particularly in installing on the roof, the construction using resin film can be made as the one excellent in the earthquake-proof performance. In addition, operating embossing treatment on the film allows reducing surface reflection of a sunlight. And, processing in the installation site is easy to operate. From these points, as the surface member, the resin film is preferably used.

For the resin film, the fluorine resin film is particularly preferable because it is particularly excellent in weather resistivity and dirt resistivity. Specifically, it is exemplified by polyvinylidene fluoride resin, polyvinyl fluoride resin, and tetrafluoroethylene-ethylene copolymer. In view of weather resistivity, polyvinylidene fluoride is particularly excellent, and in view of compatibility of weather resistivity and mechanical strength and also clearness, tetrafluoroethylene-ethylene copolymer is excellent.

In order to improve adhering performance with the resin used for the above-described filler, it is preferable that the film is subjected to corona treatment, plasma treatment, UV irradiation, electron beams irradiation, and flame treatment.

As the surface protective layer, like a sticky sheet, the surface member integrated with the filler can be employed. In addition, in the case where the filler of the waterproofing layer fully satisfies weather resistivity, dirt resistivity, and mechanical strength, the surface member is essentially not necessary. Further, a stain protection layer such as of a photocatalyst can be applied to the surface.

If adhering performance to the waterproofing layer is required when using glass or film as the surface member, adhesion is carried out by using the adhesive material or the sticky material. Specifically, it is exemplified by the filler used for forming the waterproofing layer , rubber-based, silicone-based, acrylate-based, and vinylether-based materials. Among these materials, silicone-based and acrylate-based materials are excellent in heat resistivity and weather resistivity and thus, particularly preferable. The adhesive material or the sticky material yields a desired adhesion to the above-described base member by using entirely or partially in several points.

In order to increase further the fire protection performance, as shown in the FIG. 1B, a metal foil or a metal plate 3 can be inserted in the surface protective layer 5. In this case, in consideration of a roof-following performance, a thin member is preferable to prevent bending of the material, when a large stress occurs by heat in fire and therefore, the metal foil or the metal plate with a thickness of 0.3 mm or smaller, preferably the thickness ranging from 0.02 mm to 0.2 mm is used. As a kind of metal, stainless steel, iron, aluminum, various plated steel plates, and alloy can be used, and among these materials, stainless steel is preferably used. In this case, in order to cover carry out the covering of the metal, the metal may be sealed in the filler used for the above-described waterproof means.

In addition, to assist degassing in the manufacturing procedure, the sheet member made of a fiber material can be inserted. The material can be exemplified by a glass fiber nonwoven fabric, glass fiber woven fabric, and the like. The glass fiber nonwoven fabric is more advantageous in cost, and when using the thermoplastic resin as the filler, a space between glass fibers can be filled readily with the thermoplastic resin and thus, it is more preferable.

Next, The facing material of the present invention will be described on the basis of installation state.

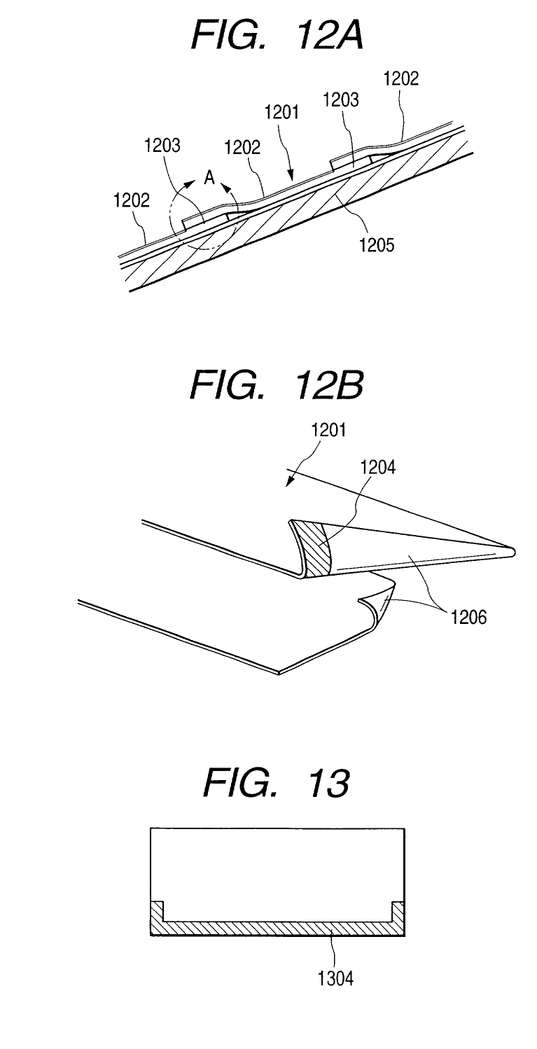

FIG. 12A and FIG. 12B show one example of installation of the facing material 1201 on the roof 1205. Normally, in the case where it is installed on a portion such as the roof or a wall, of which area is large, a plurality of the facing materials are used and the facing materials are installed overlapping each other so as to keep the waterproof performance. In this case, an exposed region 1202 and unexposed region 1203 occur for each facing material. In this case, even if there is the water-absorption preventing layer 1204 in a portion (a region of a flame resistive layer, in which the facing materials overlap each other) of the exposed region of the present facing material, other facing material is located thereunder and the flame resistive layer 1206 exists and therefore, the fire protection performance is kept. As shown in a back view of FIG. 13, normally, such water-absorption preventing layer 1304 is provided in a peripheral portion of the facing material.

In addition, in the unexposed region as shown in FIG. 15, when fixing to the roof substrate and a wall substrate 1502 with a nail or a screw 1501, simple fixing may be possible, however, in order to prevent break of the facing material by excessive driving of the nail or the screw, a fixing support means 1503 such as a metal plate or a metal foil may be provided in the unexposed region. In addition, when making sure fixing and using no nail and screw, an adhesive material or a sticky material may be used as the adhesion means.

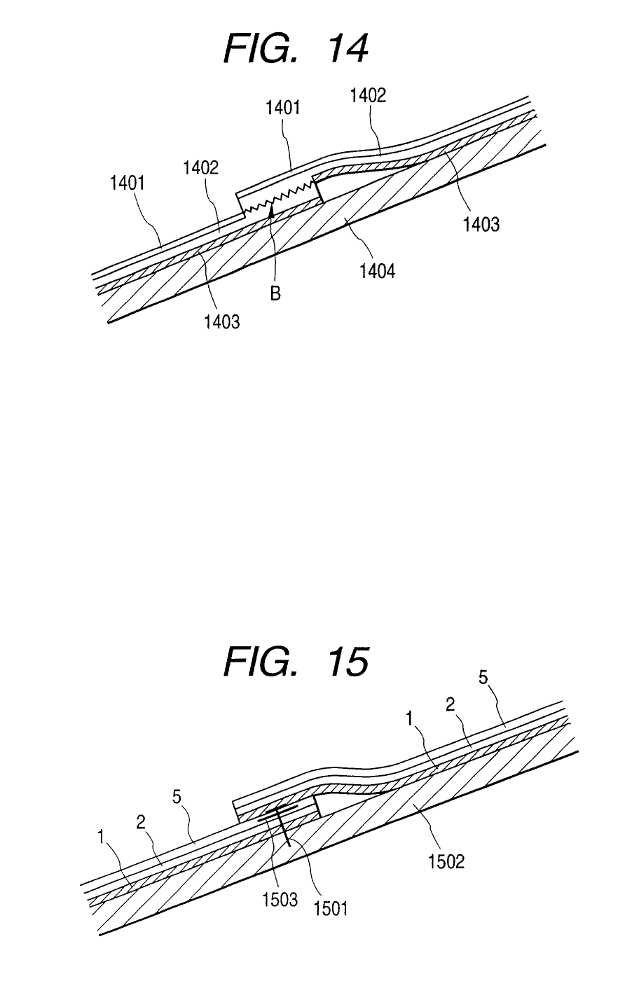

Furthermore, when overlapping the facing materials, water may be sucked up by capillary phenomenon in the waterproofing layer , the surface protective layer, and the water-absorption preventing layer to disturb to keep watertightness. Watertightness is increased by using the adhesive material or the sticky material, and watertightness can be improved by providing an irregular surface as shown in the part B of FIG. 14 and combination of these. In FIG. 14, reference numerals 1401, 1402, 1403, and 1404 denote the surface member, the waterproofing layer the flame resistive layer, and the roof substrate, respectively.

The second preferred embodiment of the present invention will be described below. However, the present invention is not restricted to the present embodiment.

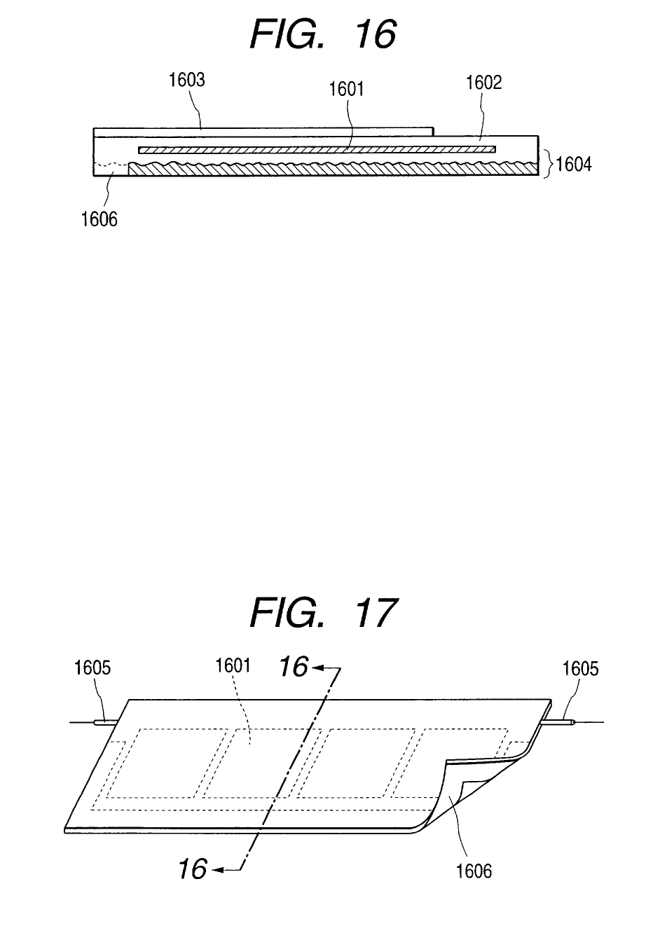

FIG. 17 is a perspective view showing the solar cell module of the present invention. FIG. 16 is a schematical cross-sectional view taken along the line 16-16 of FIG. 17. As shown in these figures, the solar cell module of the present invention has a structure, in which a photovoltaic element 1601 is covered with a filler 1602, and a surface member 1603 is installed on a light-receiving face side thereof, and the covering means 1604 made of fibers having the flame resistive performance is installed on a non-light-receiving face side thereof. In FIG. 16 and FIG. 17, the reference numeral 1605 represents an electric output line and the reference numeral 1606 represents the water-absorption preventing layer.

Each element of the solar cell module of the present invention will be described below.

(Photovoltaic Element)

The photovoltaic element used for the present invention is not specially restricted and a silicon semiconductor, a compound semiconductor, and the like can be used. Of the silicon semiconductors, single-crystal silicon, polycrystal silicon, amorphous silicon, thin film polycrystal silicon, and a combination of them can be used.

The photovoltaic element, inside the solar cell module, in order to yield a desired voltage and current, several solar cell elements can be used in a series or parallel arrangement. In addition, for the structure of the photovoltaic element, a wafery photovoltaic element and the photovoltaic element, of which substrate is prepared by stainless steel, glass or film, can be used.

(Filler)

The filler is used to cover the irregular surface of the photovoltaic element 1, protect the photovoltaic element 1 from such severe external environment as a temperature change, humidity, and shock, and keep adhesion of the surface member and the back face member with the photovoltaic element 1. Therefore, weather resistivity, adhesion, fillability, heat resistivity, cold resistivity, anti-shock performance are required. As the resin to satisfy these requirements, specifically, ethylene-vinyl acetate copolymer (EVA), ethylene-methyl acrylate copolymer (EMA), ethylene-ethyl acrylate copolymer (EEA), and polyvinyl butylal resin are enumerated. Among these, EVA is the resin frequently used as the covering material for the conventional solar cell module and thus, gives the high reliability without changing largely the constitution of a conventional filler, and is low in cost, and thus, is the most preferable material.

In the case where the photovoltaic element has weather resistivity and the like, when the photovoltaic element does not require sealing, and in the case where a sealed photovoltaic element is adhered to the covering means, when only adhering performance to the covering means is necessary, an adhesive material or a sticky material may be used as the filler. In this case, specifically, rubber-based, silicone-based, acrylate-based, and vinyl ether-based materials are enumerated. Among these materials, silicone-based and acrylate-based materials are excellent in heat resistivity, weather resistivity, and electric insulation and thus, particularly preferable. The adhesive material or the sticky material yields the desired adhesion to the covering means by using it entirely or partially in several points.

As the filler, the above-described materials may be combined.

In addition, to keep electric insulation of the photovoltaic element from the outside, an insulation film may be inserted in the filler as an insulation layer. Normally, only filling the back face with an organic polymer resin allows keeping electric insulation. However, if the configuration of the photovoltaic element is susceptible of irregular thickness of the organic polymer resin and an electroconductive member is used for the covering means, short circuit can occur and therefore, use of the insulation film allows keeping safety further.

As the material of the insulation film, preferable are materials capable of satisfactory electrical insulation from the outside, excellent in long term tolerance, tolerable to thermal expansion and heat-shrinking, and having flexicibility. As the film usable preferably, nylon, polyethylene terephthalate, and polycarbonate are enumerated.

In order to assist degassing in the manufacturing procedure, a sheet member made of a fiber material can be inserted. As the material for the sheet member, the glass fiber nonwoven fabric and the glass fiber woven fabric are exemplified. The glass fiber nonwoven fabric is more preferable, because it is more advantageous in cost and because when using the thermoplastic resin as the filler, the thermoplastic resin can be readily used for filling between glass fibers.

(Surface Member)

The surface member is located in the uppermost surface of the solar cell module to use as a surrounding device for protection of the solar cell module from outside dirt and protect from injury and humidity caused by the outside. Therefore, clearness, weather resistivity, dirt resistivity, and mechanical strength are required. As the material to satisfy such requirement and usable preferably, glass, fluorine resin film and acrylic resin film are exemplified.

Particularly the resin film having flexibility does not break by shock from outside. In addition, the resin film, in comparison with glass, is very light material and therefore, the weight of the solar cell module is reduced. In other words, particularly when installing on the roof, a construction using it can become excellent in earthquake-proof performance. In addition, embossing treatment to the film can reduce the surface reflection of sunlight. Processing can be easily carried out on the installation site. In these points, the resin film is preferably used as the surface member.

Of resin films, the fluorine resin film is particularly preferable due to particularly excellent weather resistivity and dirt resistivity. Specifically, the resin therefor includes polyvinylidene fluoride resin, polyvinyl fluoride resin, and tetrafluoroethylene-ethylene copolymer. In view of weather resistivity, polyvinylidene fluoride resin is particularly excellent, and in view of compatibility of weather resistivity and mechanical strength and also clearness, tetrafluoroethylene-ethylene copolymer is excellent.

In order to improve adhering performance with the resin used for the above-described filler, it is preferable that the film is subjected to the surface treatment such as corona treatment, plasma treatment, ozone treatment, UV irradiation, electron beam irradiation, and flame treatment. In addition to these, like a sticky sheet, the surface member integrated with the filler can be used.

When using glass as the substrate for the photovoltaic element, glass can take a role of the surface member by using glass on the light-receiving face side. In addition, in accordance with a place of use, the surface member can be omitted in the case where the filler satisfies enough weather resistivity, dirt resistivity, and mechanical strength and the case where a dirt protective layer of photocatalyst is used on the surface.

(Covering Means)

For the covering means applied to the present invention, the fibers having flame resistivity are used. Here, “having flame resistivity” means that one having 26.5 or higher of limiting oxygen index (LOI) defined in JIS K7201, and the fibers having “a property showing less melting and shrinking degrees even by approaching to the flame in air to keep almost the original shape thereof” or the fibers having incombustibility are used. For example, those are exemplified by heat resistive and flame resistive fibers such as glass fiber, ceramic fiber, various metal fiber, and metal wire, aramid fiber, novoloid fiber, and polybenzimidazole fiber, flame retardant rayon, flame retardant polyester, flame protective wool, modacryl, aromatic polyamide, and carbon fiber.

In addition, there are flame resistive fibers and the like yielded by a treatment for realizing flame resistivity by the known method using organic fibers such as acrylonitrile-based fibers, rayon fibers, pitch-based fibers, and phenol-based fibers, as the precursor. Among these fibers, flame resistive fibers used as the precursor of the carbon fibers prepared by firing and carbonization (oxidation) of the special acrylic fibers has about 50 of the limiting oxygen index and has no electroconductivity like the carbon fiber, allows cost reduction, and thus, is preferable as the covering means in insulation performance. As the covering means of the solar cell module, it is possible to use sheet-like member which is prepared by processing these fibers to produce nonwoven fabric, felt, textile, jersey, or mesh so as to have voids or irregular portions on at least one face, and its productivity is good. Further, blended yarn fibers having the above-mentioned performance may be used. Furthermore, in order to obtain flexibility, increased strength or the like, fibers having no above-mentioned performance may be mixed with the fibers having the above-mentioned performance so far as the object of the present invention can be accomplished as a whole. Even when a binder is adopted for making the fibers to the sheet in the manufacturing procedure, if the flame resistive performance is kept, use of the binder is in the range of the present invention.

In addition, as described for the filler, the glass fiber-nonwoven fabric in which a resin has been impregnated does not satisfy the requirement as the covering means of the present invention, because the resin melts at approaching to the flame.

(Electric Output Line)

For the electric output line used in the present invention, no special restriction has been made and selection should be carried out from electric output lines having heat resistivity, cold resistivity, mechanical strength, electric insulation, waterproof performance, oilproof performance, antifriction performance, antiacid performance, and alkali resistive performance required in accordance with an environment of use. For example, an electrically insulated wire made of IV, KIV, HKIV, cross-linking polyethylene, fluorine rubber, silicone rubber, and fluorine resin are enumerated. As the electric output line, a copper tub, a copper wire and the like other than the electric wires are also usable.

The preferable structure is a cable structure when particularly requiring injury resistive performance and antifriction performance according to a situation of use. However, a flat type electric wire and a ribbon type electric wire are also usable.

Specifically, 600 V polyethylene cables (EV, EE, CV, CE) of JIS C3605 standard; 600 V EP rubber insulation cables (PN and PV) of JIS C3621 standard; 600 V vinyl insulation vinyl sheath (flat type) cables (VVR and VVF) of JIS C3342 standard; class 1, class 2, class 3, and class 4 rubber insulation rubber cab tyre cables (1CT, 2CT, 3CT, and 4CT) of JIS C3327 standard; class 2, class 3, and class 4 rubber insulation chloroprene cab tyre cables (2RNCT, 3RNCT, and 4RNCT) of JIS C3327 standard; class 2, class 3, and class 4 EP rubber insulation chloroprene cab tyre cables (2PNCT, 3PNCT, and 4PNCT) of JIS C3327 standard; or a vinyl insulation vinyl cab tyre cables of JIS C3312 standard can be used.

In FIG. 17, the electric output line was drawn from a side part and may be drawn from the non-light-receiving face side or the light-receiving face side. When the electric output line was drawn from the side part or the light-receiving face side, inspection can be readily carried out, and when a distance between the solar cell module and the roof substrate is not kept, easy wiring becomes possible.

(Water-absorption Preventing Layer)

In the state that flame resistive fibers of the covering means are exposed to a portion where the solar cell modules are overlapped, water invades the back side of the solar cell modules by capillary phenomenon to make leaking of rain possible. In order to prevent such phenomenon and protect the construction, the water-absorption preventing layer 1606 is provided. For this purpose, the above-described filler is impregnated in the space of the covering means and the above-described surface protective layers adhere to it. In addition, two or more kinds of these materials and layers may be used.

In addition, the water-absorption preventing layer may be formed by adhesion of overlapped solar cell modules using the adhesive material or the sticky material. The adhesive material is exemplified by rubber-based, silicone-based, acrylate-based, and vinylether-based materials are enumerated. Among these materials, silicone-based and acrylate-based materials are excellent in heat resistivity and weather resistivity and thus, particularly preferable.

Next, the solar cell module according to the present invention will be described based on the installation condition.

FIG. 12 shows an example of installation of the solar cell module according to the present invention as the facing material 1201 on the roof 1205. Normally, in the case where it is installed on the portion such as the roof or a wall, of which area is large, a plurality of the solar cell modules are installed by overlapping the solar cell modules so as to keep the waterproof performance. In this case, the exposed region 1202 and unexposed region 1203 occur for each solar cell module. In this case, even when there is the water-absorption preventing layer 1204, to which the flame resistive fiber has not been exposed, on the exposed region of the present solar cell module, other solar cell module is located thereunder and the covering means 1206 exists, to which the flame resistive fiber has been exposed, and therefore, the fire protection performance is kept. As shown in the back view of FIG. 13, normally, such water-absorption preventing layer 1304 is provided in a peripheral portion of the solar cell module.

In addition, similarly as in fixing of the facing material, in the unexposed region as shown in FIG. 15, when fixing to the roof substrate and the wall substrate 1502 with the nail or the screw 1501, simple fixing may be possible, however, in order to prevent break of the solar cell module by excessive driving of the nail or the screw, a fixing support means 1503 such as the metal plate or the metal foil may be provided in the unexposed region and the like. In addition, when making sure fixing or when using no nail and screw, the adhesive material or the sticky material may be used as the adhesion means.

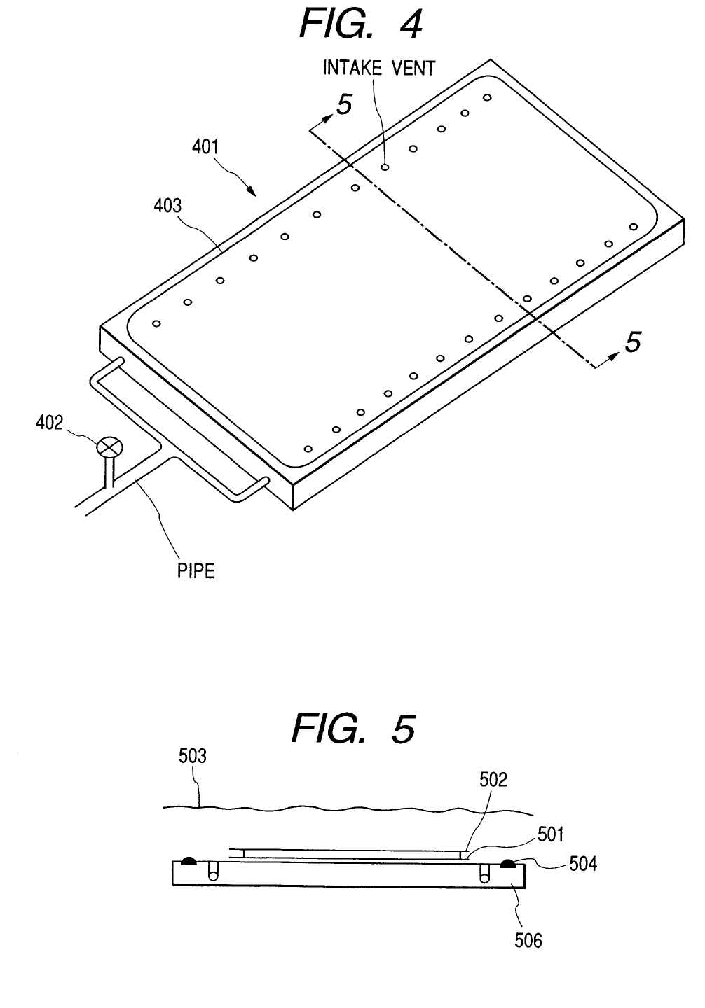

Furthermore, when overlapping the modules, water may be sucked up by capillary phenomenon in the waterproofing layer, the surface protective layer, and the water-absorption preventing layer to disturb watertightness. Watertightness can be increased by using the adhesive material or the sticky material, and watertightness can be improved by providing a irregular surface as shown in the part B of FIG. 14 or by combination of these. In FIG. 4, reference numerals 1401, 1402, 1403, and 1404 are the surface member, the filler, the covering means, and the roof substrate, respectively.

The third preferred embodiment of the present invention will be described below. However, the present invention is not restricted to the present embodiment.

FIG. 24 is a perspective view showing the solar cell module of the present invention. FIG. 23 is a schematical cross-sectional view taken along the line 23-23 of FIG. 24. As shown in these figures, the solar cell module of the present invention has the structure in which the photovoltaic element 2301 is covered with the filler 2302 and the surface member 2303 is installed on the light-receiving face thereof and the covering means 2304 composed of fibers having the flame resistive performance, is installed on the non-light-receiving face. In FIG. 23 and FIG. 24, the reference numeral 2305 represents the electric output line.

The first preferred embodiment according to the present invention will be described below in detail with reference to the following examples. However, the present invention is not restricted to these examples.

### EXAMPLE 1

This example as shown in the FIG. 3 employed, as the surface member 301, the fluorine resin film having a thickness of 50 μm; and as the base member of the flame resistive layer 303 and the waterproofing layer 302, a 200 g/m² felt with the thickness of about 3 mm which was made of flame resistive fibers (manufactured by Asahi Kasei Industry Co., Ltd., Lastan (registered trademark)) from precursors of the acrylic fibers. The filler of the waterproofing layer 302 was of a 230 μm thick EVA resin (ethylene-vinyl acetate copolymer) used for the portion between the surface member and the above-described base member.

For production of the roofing material, a Teflon film 501 for mold releasing is mounted on a jig 401/506 shown FIG. 4 and FIG. 5, and thereupon, a stacked body 502 is mounted which is prepared by stacking sequentially a felt-like flame resistive fibers (base member), a sheet-like filler and a surface member. Thereafter, the stacked body is covered with a silicone rubber 503 and in this state, a vacuum pump not illustrated is worked and a valve 402 is opened. Then, the silicone rubber 503 is closely contacted to an O-ring 403/504, and a space between the silicone rubber 503, the O-ring 403/504, and an aluminum-made plate of the jig 401/506 is made in a vacuum state of inside thereof. According to this step, the base member, filler, and the surface member are pressed evenly to the jig by an atmospheric pressure through the silicone rubber.

The jig in such state is put into a heating furnace and the like, while the vacuum pump is worked to keep a vacuum state. A temperature inside the heating furnace is kept at a temperature over a melting point of the above-described filler. After the passage of a time during which the filler in the heating furnace softens at the temperature over the melting point and a chemical change for expressing an enough adhesion is completed, the jig keeping in the above-described vacuum state is taken out from the heating furnace. After this is cooled to a room temperature, the working of the vacuum pump is stopped and the silicone rubber is removed to release from the vacuum state. According to these steps, the roofing material can be yielded.

### EXAMPLE 2

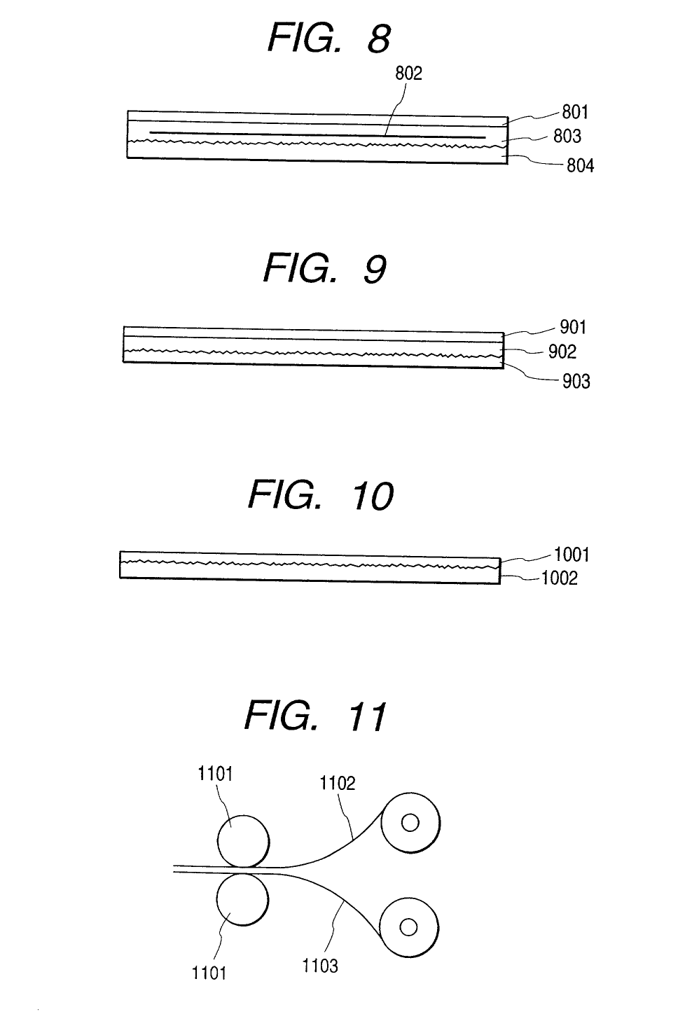

In this example as shown in FIG. 8, as the surface member 801, the fluorine resin film of a thickness of 50 μm was used, and as the base member of the flame resistive layer 804 and the waterproofing layer 803, a 200 g/m² felt with the thickness of about 3 mm which was made of the flame resistive fibers (manufactured by Asahi Kasei Industry Co., Ltd., Lastan (registered trademark)) from precursors of the acrylic fibers. The filler of the waterproofing layer 803 was EVA resin (ethylene-vinyl acetate copolymer) prepared in a 250 μm thick sheet-like form, and it was arranged in both sides of the light-receiving face side and the non-light-receiving face side of a coated stainless steel plate 802 with the thickness of 125 μm to form the waterproofing layer 803. Here, the filler is adapted so as not to reach the back face of the base member by keeping the flame resistive layer 804, thereby finally resulting in the roofing material.

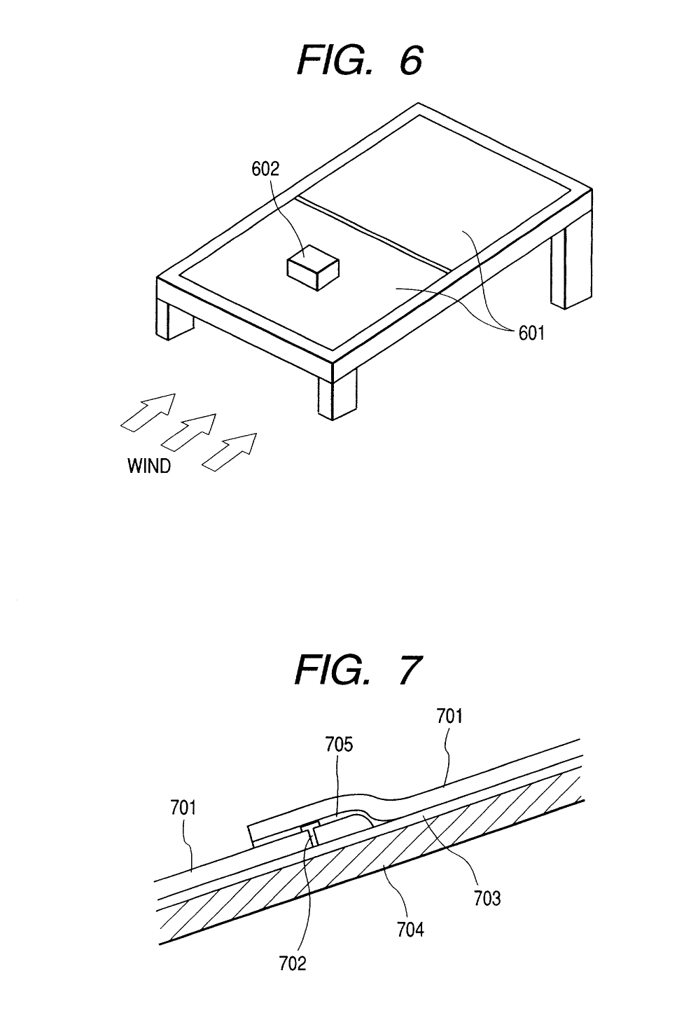

As shown in FIG. 7, asphalt roofing 703 is put on the sheathing roof board 704 made of a plywood with the thickness of 12 mm and then, the roofing material 701 is put thereon to fix by a drill screw 702 and a butyl tape 705. The imitation roof having such cross section of FIG. 7 is prepared as shown in FIG. 6. A torch 602 of about 550 g of Douglas fir was put on the roofing material 601 to burn by sending a wind of a 3-m velocity for a test of roof protection from fire. After the test, the back face of the sheathing roof board was not burnt and thus, an excellent fire protective result was obtained. The result was brought by the fact that the filler has not been impregnated up to the back face of the base member, the flame resistive layer 804 excellent in a fire blocking performance is kept in the back face of the roofing material, and the back face of the roofing material has the structure lacking any combustible matter. According to this, the fire protective performance of the roofing material of the present invention could be proven.

### EXAMPLE 3

In this example as shown in FIG. 9, a glass plate was used as the surface member 901, and as the flame resistive fibers used for the base member of the flame resistive layer 903 and the waterproofing layer 902, the flame resistive fibers (manufactured by Asahi Kasei Industry Co., Ltd., Lastan (registered trademark)) from precursors of the acrylic fibers were used to form a 200 g/m² felt with the thickness of about 3 mm as the base member. The filler of the waterproofing layer 902 was EVA resin (ethylene-vinyl acetate copolymer) prepared in the sheet-like form, and it was used to produce the roofing member with a vacuum laminator for the solar cell. Here, the filler was adapted not to reach the back face of the base member to keep the flame resistive layer 903, thereby finally resulting in the roofing material.

For this roofing material, the test of roof protection from fire was conducted by employing the same installation method as that of Example 2. However, despite that break was found in glass of the surface, after the test, it was found that the back face of the sheathing roof board was not burnt. This result is excellent for fire protection. The result was brought by the fact that even when glass was broken, the back face of the roofing material has the flame resistive layer 903 excellent in the fire blocking performance to prevent falling down of sparkles and other combustible matters on the roofing material on the roof and also prevent direct contact of a fire source to the roofing material. These reasons have proven an effect of the roofing material of the present invention.

### EXAMPLE 4

In this example as shown in FIG. 10, as the flame resistive fibers used for the base member of the flame resistive layer 1002 and the waterproofing layer 1001, the flame resistive fibers (manufactured by Asahi Kasei Industry Co., Ltd., Lastan (registered trademark)) from precursors of the acrylic fibers were used to form a 200 g/m² felt with the thickness of about 3 mm as the base member. The filler of the waterproofing layer 1001 was ethylene-methyl acrylate copolymer (EMA) prepared in the sheet-like form, and the roofing material was produced as shown in FIG. 11, by passing this filler material sheet 1102 through a heating and pressing roll 1101 in order to adhere the sheet with the flame resistive fibers (base member) 1103.

As described above, the facing material of the present invention presents the following effects.

Use of the fibers having the flame resistive performance as the covering means of the back face improves the fire protection performance. Particularly, in the case where the resin or the adhesive used for the filler in the covering means has not impregnated up to the non-light-receiving face side of the facing material or where there is the metal foil or the metal plate on the surface protective layer, the fire protection performance is further improved.

In addition, the sheet is composed of fibers and therefore, the weight per the area becomes small, and the installation performance is good and also structural calculation can be advantageously carried out and therefore, cost of a skeleton of the construction can be reduced.

Further, the materials of the facing material can be stacked integrally and thus, productivity is improved.

And, in the case there is the water-absorption preventing layer on the back face, this is located on the unexposed region of another facing material and therefore, the fire protection performance is kept and also the waterproof performance can be increased.

In addition, the facing material has the face configured with fibers and hence, the facing material can be transported and kept in the condition of stacking in the same direction to allow reducing the packing cost.

The second preferred embodiment according to the present invention will be described below in detail with reference to the following examples. However, the present invention is not restricted by these examples.

### EXAMPLE 5

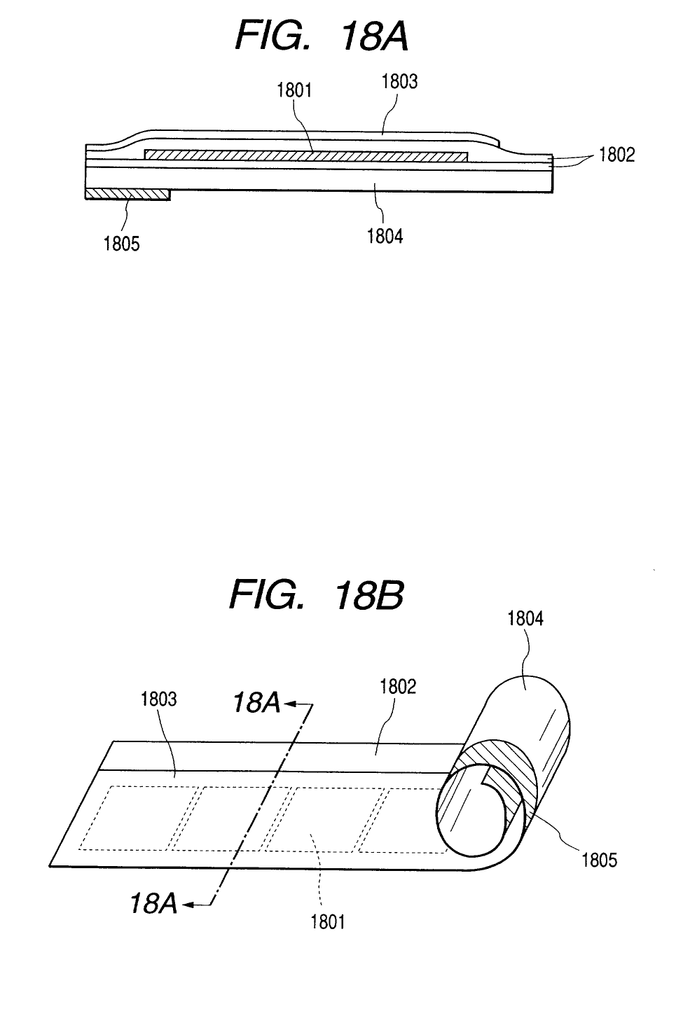

FIG. 18B is a perspective view showing the solar cell module of this example. FIG. 18A is a cross-sectional view taken along the line 18A-18A of FIG. 18B. As the photovoltaic element 1801, an amorphous silicon photovoltaic element prepared by forming an amorphous silicon semiconductor layer on a stainless steel substrate of a 125 μm thickness was used, and as the surface member 1803, a fluorine resin film of the thickness of 50 μm was used in other region than a portion of the unexposed region. As the covering means 1804, a 200 g/m² felt with the thickness of about 3 mm was used which was made of the flame resistive fibers (manufactured by Asahi Kasei Industry Co., Ltd., Lastan (trade mark registered,)) from precursors of the acrylic fibers. As the filler 1802, sheet with a thickness of 450 μm thick EVA resin (ethylene-vinyl acetate copolymer) was used and arranged on the light-receiving face side of the photovoltaic element, and one with the 230 μm thick EVA resin was used and arranged on the non-light-receiving face side. In addition, in an end portion of the exposed region, a EVA resin with the 230 μm thick was zonally stacked as the filler 1805 on the non-light-receiving face side of the covering means.

The production of the solar cell module is conducted in the same manner as in the production of the roofing material of Example 1. Teflon film 501 for mold releasing is mounted on a jig 401/506 shown FIG. 4 and FIG. 5, and thereupon, the stacked body 502 is mounted which is prepared by stacking sequentially the felt-like covering means 1804, the sheet-like filler 1802, the photovoltaic element 1801, the filler 1802, and the surface member 1803. Thereafter, the stacked body is covered with the silicone rubber 503 and in this state, the vacuum pump not illustrated is worked and the valve 402 is opened. Then, the silicone rubber 503 is contacted closely to the O ring 403/504 to form a space between the silicone rubber 503, the O ring 403/504, and the aluminum-made plate of the jig 401/506, and the inside is made in the vacuum state. According to this step, the covering means 1804, the filler 1802, the photovoltaic element 1801, the filler 1802, and the surface member 1803 are pressed evenly to the jig by the atmospheric pressure through the silicone rubber.

By using the jig in such state, the vacuum pump is worked and then, while keeping a vacuum state, it is put into the heating furnace and the like. The temperature inside the heating furnace is kept to the temperature over the melting point of the above-described filler. After the time when the filler in the heating furnace softens in the temperature over the melting point and the chemical change for expressing the enough adhesion is completed, the jig is taken out from the heating furnace while keeping the above-described vacuum state. After this is cooled to the room temperature, the vacuum pump is stopped to work and the silicone rubber 503 is removed to break the vacuum state. According to these steps, the solar cell module can be produced.

The solar cell module produced was stored after wound as shown in the FIG. 18B.

Similarly as the roofing material of Example 2, as shown in the FIG. 7, the asphalt roofing 703 is put on the sheathing roof board 704 made of the plywood with the thickness of 12 mm and then, the solar cell module 701 is put thereon to fix with the drill screw 702 and the butyl tape 705. As shown in FIG. 6, the imitation roof having such cross-sectional view of FIG. 7 is prepared and the torch 602 of about 550 g of Douglas fir is put on the solar cell module 601 to burn by sending the wind of the 3 m velocity for the test of roof protection from fire. By the test, it was observed that the back face of the sheathing roof board had not burnt and thus, the excellent fire protective result was obtained. The result was brought from that the solar cell module is excellent in a fire blocking performance because the filler has not been impregnated up to the back face of the covering member side of the solar cell module, that is, the structure of the back face lacks the combustible matter. In the overlapped portion, there is the layer made of only the flame resistive fibers, thereby resulting in the fire protection performance. By this, the fire protection performance of the solar cell module of the present invention was proven.

### EXAMPLE 6

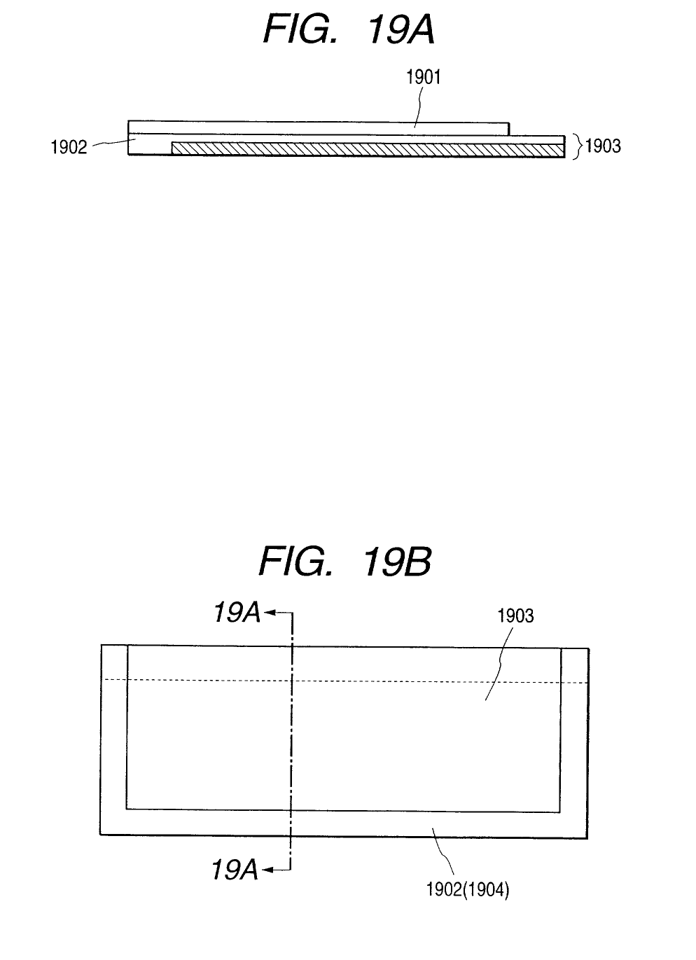

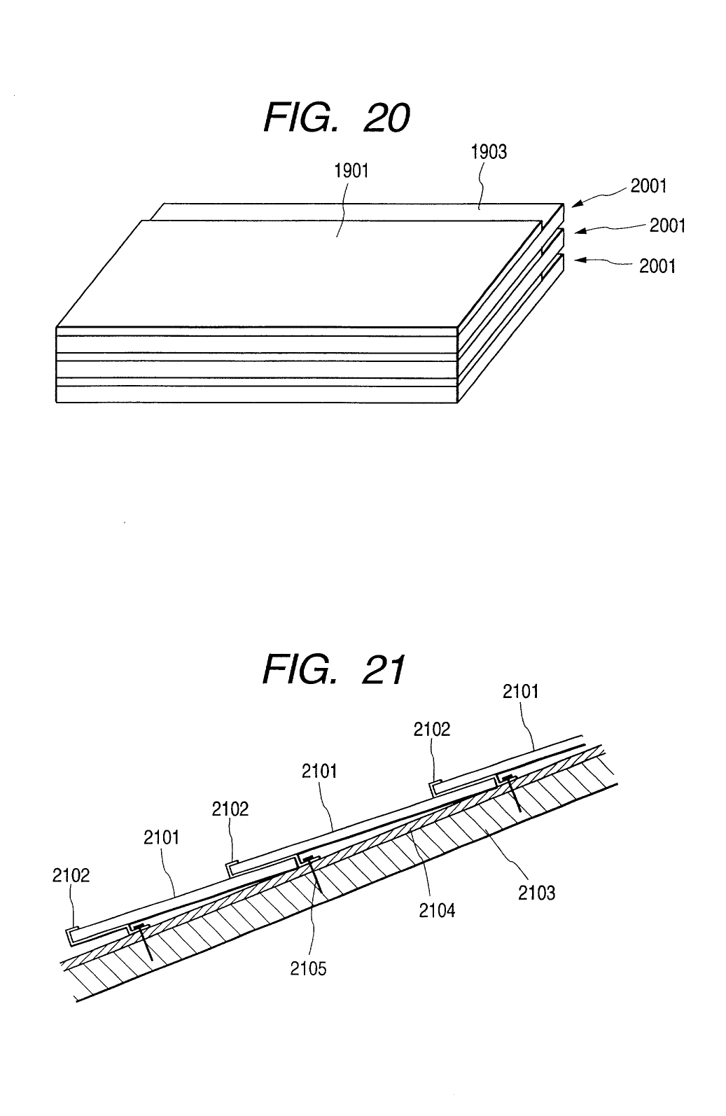

In this example as shown in FIGS. 19A, 19B and FIG. 20, as the photovoltaic element and the surface member, the amorphous silicon photovoltaic element 1901 prepared by forming the amorphous silicon semiconductor layer on the glass substrate was used, and as the covering means 1903, 200 g/m² felt with the thickness of about 3 mm which was made of the flame resistive fibers (manufactured by Asahi Kasei Industry Co., Ltd., Lastan (trade mark registered,)) from precursors of the acrylic fibers was used. As the filler 1902, a sheet-like EVA resin (ethylene-vinyl acetate copolymer) was used and arranged on the back face of the photovoltaic element and the end 1904 of the light-receiving region of the back face of the covering means to prepare the solar cell module by the vacuum laminator for the solar cell.

The solar cell module 2001 produced was stored in a stacked state as shown in the FIG. 20.

The solar cell module is installed as shown in the FIG. 21; the asphalt roofing 2104 is put on the sheathing roof board 2103 configured by the plywood with the thickness of 12 mm and then, the solar cell module 2101 is put thereon and the fixing member 2102 is arranged with the drill screw 2105. In the imitation roof prepared by the above manner is prepared as similar to Example 5, the torch of about 550 g of Douglas fir is put on the solar cell module to burn by sending the wind of the 3 m velocity for the test of roof protection from fire. By the test, it was observed that in spite of finding of break of the surface glass, the back face of the sheathing roof board had not burnt and thus, the excellent fire protective result was obtained. The result was brought from that even when the glass breaks, the covering means of the solar cell module is excellent in a fire blocking performance to allow preventing falling down of sparkles and other combustible matters on the roofing material on the roof and also preventing direct contact of the fire source to the roofing material and therefore, the effect of the solar cell module of the present invention was proven.

### EXAMPLE 7

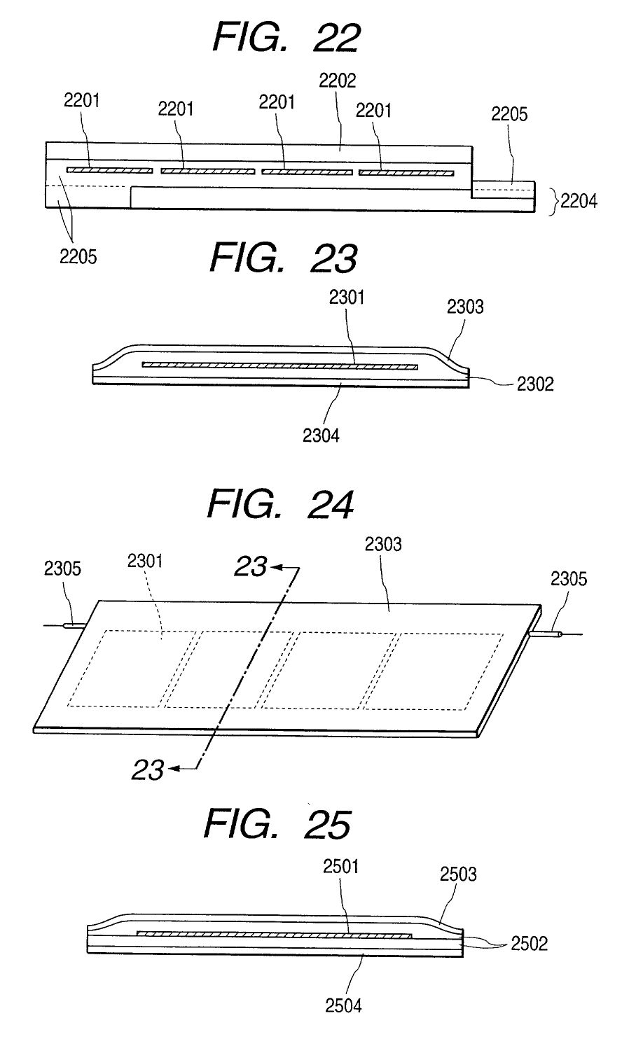

In this example as shown in FIG. 22, as the photovoltaic element 2201, the wafery polycrystal silicon solar cell was used, and the glass plate was used as the surface member 2202. As the covering means 2204, a 200 g/m² felt with the thickness of about 3 mm which was made of the flame resistive fibers (manufactured by Asahi Kasei Industry Co., Ltd., Lastan (trade mark registered,)) from precursors of acrylic fibers was used. As the filler 2205, a sheet-formed EVA resin (ethylene-vinyl acetate copolymer) was used and arranged on the front surface and the back surface of the photovoltaic element to produce the solar cell module by the vacuum laminator for the solar cell.

The produced solar cell module was subjected to the test of roof protection from fire by the same installation method as that of Example 6. Similarly to the result of Example 6, despite of finding of break of surface glass, it was observed that the back face of the sheathing roof board had not burnt and thus, the excellent fire protective result was obtained.

As described above, the solar cell module of the present invention presents the following effects.

As the covering means for the back face, the fibers having the flame resistive performance are used and therefore, the fire protection performance is improved. Particularly, in the covering means, in the case where the resin used as the filler has not impregnated up to the non-light-receiving face side of the solar cell module or in the case where the photovoltaic element has been formed on the metal plate, the fire protection performance is further improved by the photovoltaic element.

In addition, the covering means is the sheet configured by the fibers and therefore, the weight per area is small to make installation performance better, and structure calculation is advantageous and therefore, cost of the skeleton of the construction can be reduced.

Further, the solar cell module can be stacked integrally and thus, productivity is improved.

And, in the case there is the water-absorption preventing layer on the back face of the solar cell module, this is located on the unexposed region of another the solar cell module and therefore, the fire protection performance is kept and also the waterproof performance can be increased.

In addition, the facing material has the face configured with fibers and hence, the facing material can be transported and kept in the condition of stacking in the same direction to allow reducing the packing cost.

The third preferred embodiment according to the present invention will be described below in detail with reference to the following examples. However, the present invention is not restricted to these examples.

### EXAMPLE 8

In this example as shown in the FIG. 25, as the photovoltaic element 2501, the amorphous silicon photovoltaic element prepared by forming the amorphous silicon semiconductor layer on the stainless steel substrate of 125 μm thickness was used, and as the surface member 2503, the fluorine resin film of the thickness of 50 μm was used. As the covering means 2504, a 200 g/m² felt with the thickness of about 3 mm which was made of the flame resistive fibers (manufactured by Asahi Kasei Industry Co., Ltd., Lastan (trade mark registered,)) from precursors of the acrylic fibers was used. As the filler 2502, a sheet of 450 μm thick EVA resin (ethylene-vinyl acetate copolymer) was used and arranged on the light-receiving face side of the photovoltaic element and a sheet of 230 μm thick of EVA resin was used and arranged on the non-light-receiving face side.

The production of the solar cell module is conducted similarly as in Example 1; the Teflon film 501 for mold releasing is mounted on the jig 401/506 shown FIG. 4 and FIG. 5, and thereupon, the stacked body 502 is mounted which is prepared by stacking sequentially the felt-like covering means 2504, the sheet-like filler 2502, the photovoltaic element 2501, the filler 2502, and the surface member 2503. Thereafter, the stacked body is covered with the silicone rubber 503 and, in this state, the vacuum pump not illustrated is worked and the valve 402 is opened. Then, the silicone rubber 503 is contacted closely to the O ring 403/504 to form a space between the silicon rubber 503, the O ring 403/504, and the aluminum-made plate of the jig 401/506, thereby resulting in the vacuum state of inside thereof. According to this step, the covering means 2504, the filler 2502, the photovoltaic element 2501, the filler 2502, and the surface member 2503 are pressed evenly to the jig 401/506 by the atmospheric pressure through the silicone rubber 503.

While using the jig in such state, the vacuum pump is worked and then to keep a vacuum state, the jig is put into the heating furnace and the like. The temperature inside the heating furnace is kept to the temperature over the melting point of the above-described filler. After the filler in the heating furnace softens in the temperature over the melting point and the chemical change for expressing the enough adhesion is completed, the jig is taken out from the heating furnace while keeping in the above-described vacuum state. After this is cooled to the room temperature, the working of the vacuum pump is stopped and the silicone rubber is removed to break the vacuum state. According to these steps, the solar cell module can be obtained.

Similarly as in production of the roofing material of Example 2, as shown in the FIG. 7, the asphalt roofing 703 is put on the sheathing roof board 704 configured by the plywood of the thickness of 12 mm and then, the solar cell module 701 is put thereon to fix it by the drill screw 702 and the butyl tape 705. The imitation roof having such cross-section view is prepared as shown in the FIG. 6, the torch 602 of about 550 g of Douglas fir is put on the solar cell module 601 to burn by sending the wind of the 3 m velocity for the test of roof protection from fire. By the test, it was observed that the back face of the sheathing roof board had not burnt and thus, the excellent fire protective result was obtained. The result was brought from that the solar cell module is excellent in a fire blocking performance and also the filler has not been impregnated up to the back face of the covering member side of the solar cell module, and therefore the structure of the back face lacks the combustible matter. According to this, the fire protective performance of the solar cell module of the present invention could be proven.

### EXAMPLE 9

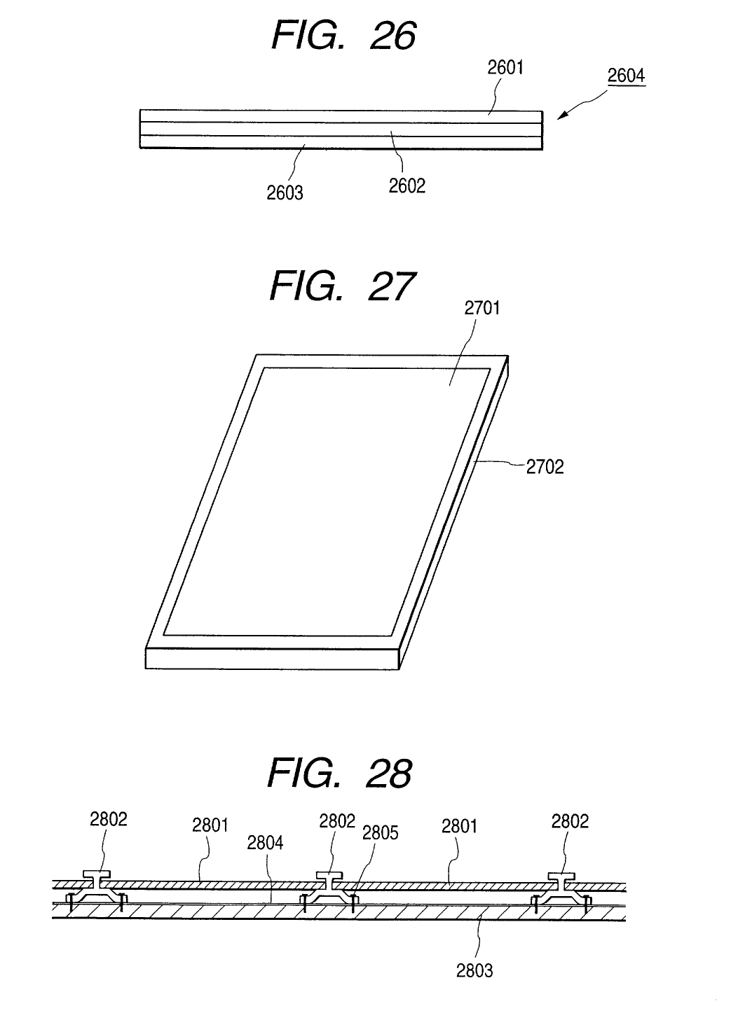

In this example as shown in the FIG. 26 and FIG. 27, as the photovoltaic element and the surface member, the amorphous silicon photovoltaic element 2601 prepared by forming the amorphous silicon semiconductor layer on the glass substrate was used, and as the covering means 2603, a 200 g/m² felt with the thickness of about 3 mm which was made of the flame resistive fibers (manufactured by Asahi Kasei Industry Co., Ltd., Lastan (trade mark registered,)) from precursors of acrylic fibers was used. As the filler 2602, a sheet-like EVA resin (ethylene-vinyl acetate copolymer) was used and arranged on the back face of the photovoltaic element to produce the solar cell panel 2604 by the vacuum laminator for the solar cell, and finally, as shown in the FIG. 27, an aluminum frame 2702 was attached to a circumferential part of the solar cell panel 2701 to produce the solar cell module.

As shown in the FIG. 28, the asphalt roofing 2804 is put on the sheathing roof board 2803 configured by the plywood of the thickness of 12 mm and then, the fixing members 2802 with the drill screws 2805, and further the solar cell module 2801 is set to the fixing members. The imitation roof prepared in such manner is tested similarly to Example 8. The torch of about 550 g of Douglas fir is put on the solar cell module to burn by sending the wind of the 3 m velocity for the test of roof protection from fire. By the test, it was observed that in spite of finding of break of the surface glass, the back face of the sheathing roof board had not burnt and thus, the excellent fire protective result was obtained.

The solar cell module was produced by using the nonwoven fabric made of glass fibers, in which EVA has been impregnated, in place of the covering means of this example, and the same test was conducted. As the result, the EVA resin melted dropped down from the nonwoven fabric made of the glass fibers and thus, the roofing was fired.

In the present invention, even when the glass breaks, the covering means of the solar cell module is excellent in a fire blocking performance and has the layer lacking the combustible resin and hence, can prevent falling down of sparkles and other combustible matters on the roofing material on the roof and also prevent direct contact of the fire source to the roofing material and therefore, the effect of the solar cell module of the present invention was proven.

### EXAMPLE 10

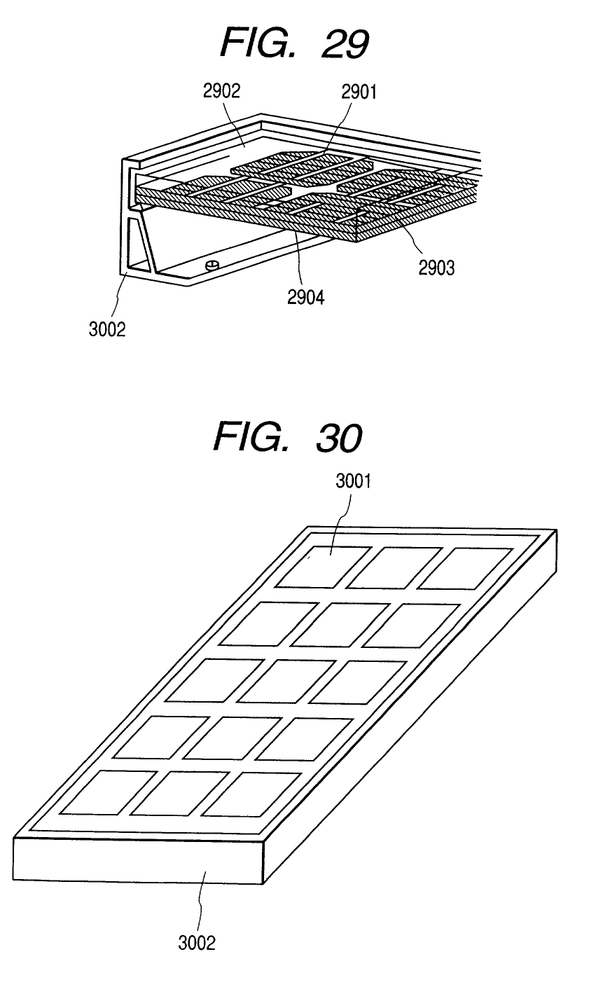

In this example as shown in the FIG. 29, as the photovoltaic element 2901, the wafery polycrystal silicon solar cell was used, and the glass plate was used for the surface member 2902. As the covering means 2904, a 200 g/m² felt with the thickness of about 3 mm which was made of the flame resistive fibers (manufactured by Asahi Kasei Industry Co., Ltd., Lastan (trade mark registered,)) from precursors of acrylic fibers was used. As the filler 2903, a sheet-formed EVA resin (ethylene-vinyl acetate copolymer) was used and arranged on the surface and the back face of the photovoltaic element to produce the solar cell module by the vacuum laminator for the solar cell, and finally, as shown in the FIG. 30, the aluminum frame 3002 was attached to the circumferential part of the solar cell panel 3001 to produce the solar cell module.

The solar cell module was subjected to the test of roof protection from fire by the same installation method as that of Example 9. The result similar to Example 9 was obtained; despite of finding of break of surface glass, it was observed that the back face of the sheathing roof board had not burnt and thus, the excellent fire protective result was obtained.

### EXAMPLE 11

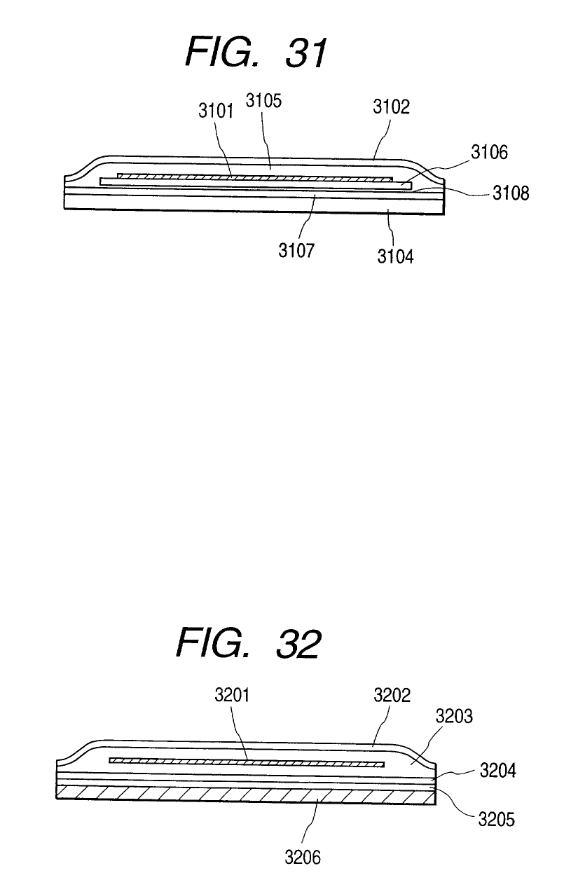

In this example as shown in the FIG. 31, as the photovoltaic element 3101, the amorphous silicon photovoltaic element prepared by forming the amorphous silicon semiconductor layer on the stainless steel substrate of 125 μm thickness was used, and as the surface member 3102, the fluorine resin film of the thickness of 50 μm was used. As the covering means 3104, a textile with an about 1-mm thickness made of carbon fibers was used. As the filler, a sheet 3105 of 450 μm thick EVA resin (ethylene-vinyl acetate copolymer) was used and arranged on the surface of the photovoltaic element and a sheet 3106 of 230 μm thick EVA resin was used and arranged on the back face of it. The carbon fibers used as the covering means 3104 were electroconductive and thus, insulation of the back face was conducted by using polyethylene terephthalate as the insulation film 3108, and EVA resin (ethylene-vinyl acetate copolymer) 3107 made in the 230 μm thick sheet was inserted between carbon fibers and the sheet 3106 to produce the solar cell module. Similarly to Example 9, fire protection test for the roof was conducted and then, as well, the excellent fire protective result was obtained.

### EXAMPLE 12

In this example as shown in the FIG. 32, as the photovoltaic element 3201, the amorphous silicon photovoltaic element prepared by forming the amorphous silicon semiconductor layer on the stainless steel substrate of 125 μm thickness was used, and as the surface member 3202, the fluorine resin film of the thickness of 50 μm was used. As the covering means 3206, an about 1 mm-thick mesh made of metal wires was used. As the filler 3203, two sheets of EVA resin (ethylene-vinyl acetate copolymer) were used and arranged on the front surface and the back surface of the photovoltaic element. The metal fibers used as the covering means 3206 are electroconductive and therefore insulation of the back face was conducted by using polyethylene terephthalate as the insulation film 3204 and arranging it on the back face, and a rubber type and thermal curing type silicone resin 3205 (manufactured by Toshiba Silicone, TSE3033) was applied between the insulation film and the metal mesh to adhere them. Similarly as in Example 9, fire protection test for the roof was conducted and then, as well, the excellent fire protective result was yielded.

### EXAMPLE 13

In this example, 200 g/m² Lastan of the flame resistive fibers was used as the covering means to conduct lamination. The covering means allowing almost direct observation of the light of a light source was selected by viewing through the covering means held up to the light of the light source. This manner was to determine a reliable performance of blocking the flame by lamination without effusion of the filler to the back face. In addition, the result of examination of performances of products made in other specifications is shown in Table 1. In the case where the weight (a quantity of the fibers per an unit area) is 100 g/m² (about 70 cm³/m²) or more, the flame resistive fibers exposed to the back face after lamination. The fire protection test showed the excellent fire protective result.

TABLE 1

| Specifi- | | Result of fire | |
|---|---|---|---|
| cation | Specification | protection | |
| (Weight) | (Volume) | test | Remarks |
| 50 g/m² | 36 cm³/m² | x | (Nonwoven fabric) |
| 70 g/m² | 50 cm³/m² | x | (Nonwoven fabric) |
| 100 g/m² | 71 cm³/m² | ∘ | (Nonwoven fabric 50 g/m² × 2) |
| 150 g/m² | 107 cm³/m² | ∘ | (Felt) |
| 200 g/m² | 143 cm³/m² | ∘ | (Felt) |
| 240 g/m² | 171 cm³/m² | ∘ | (Plain weave texture) |
| 300 g/m² | 214 cm³/m² | ∘ | (Plain weave texture) |
| 300 g/m² | 214 cm³/m² | ∘ | (Felt) |

In Table 1, symbol ◯ indicates no burning out of a sheathing roof board (plywood of 12 mm thick) in the test of roof protection from fire; and symbol x indicates burning out of a sheathing roof board (plywood of 12 mm thick) in the test of roof protection from fire.

As described above, according to the present invention, use of the fibers having the flame resistive performance as the covering means of the back face of the solar cell module improves the fire protection performance. Particularly, in the case where the resin used as the filler has not impregnated up to the non-light-receiving face side of the solar cell module in the covering means, the fire protection performance is further improved. When as the photovoltaic element, an amorphous silicon solar cell mounted on the stainless steel substrate is used, the photovoltaic element has a more excellent fire blocking performance and the good fire protection performance.

In addition, the sheet configured by the fibers is used for the covering means and therefore, the weight per area is small to make installation performance better and structure calculation is advantageous and therefore, the cost of the skeleton of the construction can be reduced.

Besides, the back face is composed of soft fibers and therefore, no injury caused by stacking in packing operation, and a packing form can be made easily.

Further, the solar cell module can be stacked integrally and thus, productivity is improved.

What is claimed is:

1. A facing material comprising a flame resistive fiber and a filler, wherein a waterproofing layer is formed by impregnating said flame resistive fiber with said filler, a flame resistive layer is made of said flame resistive fiber not impregnated with the filler, and said flame resistive layer is located in a surface of said facing material.

2. The facing material according to claim 1, wherein said filler is a thermoplastic resin.

3. The facing material according to claim 1, wherein said waterproofing layer and said flame resistive layer are flexible.

4. The facing material according to claim 1, wherein a water-absorption preventing layer is provided on a surface of said flame resistive layer.

5. The facing material according to claim 4, wherein said water-absorption preventing layer is provided at least in a peripheral portion of the surface of said flame resistive layer.

6. The facing material according to claim 4, wherein when partially overlapping a plurality of said facing material, an area of said water-absorption preventing layer is equal to or smaller than of an area of an unexposed region, where the unexposed region is a region of the surface of said facing material exposed to outside and an exposed region is a region of the surface said facing material not exposed to outside.

7. The facing material according to claim 6, wherein said water-absorption preventing layer is provided in an overlapped region of the surface of said flame resistive layer.

8. The facing material according to claim 6, wherein said water-absorption preventing layer is provided in a position distant from said unexposed region viewing from a surface side of said water-absorption preventing layer.

9. The facing material according to claim 4, wherein said water-absorption preventing layer is formed by impregnating the filler in said flame resistive layer.

10. The facing material according to claim 6, wherein said unexposed region has a fixing assistant means.

11. The facing material according to claim 10, wherein said fixing assistant means is a metal plate or a metal foil.

12. The facing material according to claim 6, wherein at least a part of the surface of said waterproofing layer side in said unexposed region has an adhesion means.

13. The facing material according to claim 6, wherein at least a part of the surface of said flame resistive layer side in said unexposed region has an adhesion means.

14. The facing material according to claim 1, wherein the surface of said water proofing layer side has a surface protective layer.

15. The facing material according to claim 14, wherein said surface protective layer has a surface protective film.

16. The facing material according to claim 14, wherein said surface protective layer has a metal plate or metal foil.

17. The facing material according to claim 16, wherein said metal plate or said metal foil is sealed with the filler.

18. The facing material according to claim 6, wherein the surface protective layer is provided in a region other than at least a part of said unexposed region.

19. The facing material according to claim 6, wherein at least a part of the surface of said waterproofing layer side in said unexposed region has irregularities.

20. The facing material according to claim 4, wherein said water-absorption preventing layer has irregularities.

21. A method of storing a facing material according to claim 1, comprising storing the facing material in a state of winding it in a longitudinal direction when it is transported or kept.

22. A method of storing a facing material according to claim 1, comprising storing the facing material in a state of stacking it in the same direction when it is transported and kept.

23. A manufacturing apparatus for the facing material according to claim 1, comprising a degassing means and a heating means, wherein a stacked body comprising a covering means made of flame resistive fibers and a sheet member of a thermoplastic resin is heated while degassing a space between the covering means and the sheet member to closely fix each other.

24. A manufacturing apparatus for the facing material according to claim 1, comprising a pressing means and a heating means, wherein a stacked body comprising a covering means made of flame resistive fibers and a thermoplastic resin is heated and pressed to closely contact each other.

25. A manufacturing method for the facing material according to claim 1, comprising stacking a covering means made of flame resistive fibers and a sheet member of a thermoplastic resin and heating them while degassing a space between the covering means and the sheet member to closely contact and fix each other.

26. A manufacturing method for the facing material according to claim 1, comprising arranging a covering means made of flame resistive fibers and a thermoplastic resin, heating, and pressing them to closely contact and fix each other.

27. A method for installing a facing material, comprising fixing the facing material to a roof substrate or an external wall by a fixing member, wherein said facing material is a facing material according to claim 1.

28. A construction comprising a facing material fixed to a roof substrate or an external wall by a fixing member, wherein said facing material is a facing material according to claim 1.

29. A photovoltaic power-generating apparatus, comprising a solar cell module and a facing material according to claim 1, wherein the facing material is installed in a portion not provided with the solar cell module on a plane in which the solar cell module is installed.

30. A solar cell module comprising a photovoltaic element and a covering means arranged on a non-light-receiving face side of the photovoltaic element and composed of the flame resistive fiber, wherein in the solar cell module, the surface of the non-light-receiving face side of said solar cell module has said flame resistive layer and the surface of the flame resistive layer has the water-absorption preventing layer.

31. The solar cell module according to claim 30, wherein a water-absorption preventing layer is provided at least in a peripheral part of the surface of the flame resistive layer.

32. The solar cell module according to claim 30, wherein when a plurality of solar cell modules are partially overlapped, an area of said water-absorption preventing layer is equal to or smaller than an unexposed region, where the unexposed region is a region of the surface of said solar cell module not exposed to outside and an exposed region is a region of the surface of said solar cell module exposed to outside.

33. The solar cell module according to claim 30, wherein said water-absorption preventing layer is provided in the overlapped part of the surface of said flame resistive layer.

34. The solar cell module according to claim 30, wherein said water-absorption preventing layer is provided in a position distant from said unexposed region viewing from the light-receiving face side.

35. The solar cell module according to claim 30, wherein said water-absorption preventing layer is formed by impregnating the filler in the flame resistive fiber.

36. The solar cell module according to claim 30, wherein said covering means is adhered to the non-light-receiving face side of the photovoltaic element by the filler and has a layer formed by impregnating said flame resistive layer with the filler.

37. The solar cell module according to claim 30, wherein the surface of the light-receiving face side of the photovoltaic element has a surface member.

38. The solar cell module according to claim 37, wherein said surface member has a surface protection film.

39. The solar cell module according to claim 37, wherein a part of said unexposed region has no surface member.

40. The solar cell module according to claim 30, wherein said unexposed region has a fixing assistant means.

41. The solar cell module according to claim 40, wherein said fixing assistant means is a metal plate or metal foil.

42. The solar cell module according to claim 30, wherein at least a part of the light-receiving face side of said unexposed region has irregularities.

43. The solar cell module according to claim 30, wherein said water-absorption preventing layer has irregularities.

44. The solar cell module according to claim 32, wherein at least a part of an overlapped region has an adhesion means.

45. The solar cell module according to claim 32, wherein at least a part of the light-receiving face side of said unexposed region or the non-light-receiving face side of said exposed region has an adhesion means.

46. The solar cell module according to claim 30, wherein said photovoltaic element is flexible.

47. The solar cell module according to claim 30, wherein said photovoltaic element is a photovoltaic element of amorphous silicon formed on a stainless steel substrate.

48. The solar cell module, according to claim 30, further comprising an electric output line for taking out an output of said photovoltaic element to outside of said solar cell module, wherein the electric output line is take out from a side part or a light-receiving face side of said solar cell module.

49. The solar cell module according to claim 32, wherein the solar cell module has an insulating layer between said photovoltaic element and the covering means in a region other than at least a part of said unexposed region.

50. A method for storing the solar cell module according to claim 30, comprising storing the solar cell module in a state of winding the module in the length direction when it is transported or kept.

51. A method for storing a solar cell module according to claim 30, comprising storing the solar cell module in the state of stacking the module in the same direction when the module is transported or kept.

52. A manufacturing method for a solar cell module comprising a photovoltaic element and a covering means arranged in a non-light-receiving face side of the photovoltaic element and composed of a flame resistive fiber, which comprises providing a flame resistive layer on a surface of a non-light-receiving face side of said solar cell module, and providing a water-absorption preventing layer on surface of the flame resistive layer.

53. The manufacturing method for the solar cell module, according to claim 52, wherein said water-absorption preventing layer is provided at least in a peripheral part of the surface of said flame resistive layer.

54. The manufacturing method for the solar cell module, according to claim 52, wherein when a plurality of solar cell modules are partially overlapped, an area of said water-absorption preventing layer is equal to or smaller than said unexposed region, where the unexposed region is a region of the surface said solar cell module not exposed to outside and an exposed region is a region of the surface of said solar cell module exposed to outside.

55. The manufacturing method for the solar cell module, according to claim 54, wherein said water-absorption preventing layer is provided in the overlapped part of the surface of said flame resistive layer.

56. The manufacturing method for the solar cell module, according to claim 54, wherein said water-absorption preventing layer is provided in a position distant from said unexposed region in viewing from a light-receiving face side of the photovoltaic element.

57. The manufacturing method for the solar cell module, according to claim 52, wherein said water-absorption preventing layer is formed by impregnating the flame resistive fiber with the filler.

58. The manufacturing method for the solar cell module, according to claim 52, wherein said covering means is adhered to the non-light-receiving face side of the photovoltaic element with the filler and the covering means has a layer impregnated with the filler.

59. The manufacturing method for the solar cell module, according to claim 52, wherein the surface of the light-receiving face side of the photovoltaic element has a surface member.

60. The manufacturing method for the solar cell module, according to claim 52, wherein said surface member has a surface protection film.

61. The manufacturing method for the solar cell module, according to claim 52, wherein a part of said unexposed region has no surface member.

62. The manufacturing method for the solar cell module, according to claim 54, wherein a fixing assistant means is provided in said unexposed region.

63. The manufacturing method for the solar cell module, according to claim 62, wherein said fixing assistant means is a metal plate or metal foil.

64. The manufacturing method for the solar cell module, according to claim 54, wherein at least a part of the light-receiving face side of said unexposed region has irregularities.

65. The manufacturing method for the solar cell module, according to claim 54, wherein said water-absorption preventing layer has irregularities.

66. The manufacturing method for the solar cell module, according to claim 54, wherein an adhesion means is provided in at least a part of the overlapped region.

67. The manufacturing method for the solar cell module, according to claim 54, wherein an adhesion means is provided in at least a part of the light-receiving face side of said unexposed region or at least of the non-light-receiving face side of said exposed region.

68. The manufacturing method for the solar cell module, according to claim 52, wherein said photovoltaic element is flexible.

69. The manufacturing method for the solar cell module, according to claim 52, wherein said photovoltaic element is an amorphous silicon photovoltaic element formed on a stainless steel substrate.

70. The manufacturing method for the solar cell module, according to claim 52, wherein said solar cell module has an electric output line for taking out an output of said photovoltaic element to outside of said solar cell module, and the electric output line is taken out from a side part of said solar cell module.

71. The manufacturing method for the solar cell module, according to claim 52, wherein an insulating layer is provided between said photovoltaic element and the covering means in a region other than at least a part of said unexposed region.

72. The manufacturing method for the solar cell module, according to claim 52, wherein a first sheet member of a thermoplastic resin, the covering means made of the flame resistive fiber, a second sheet member of a thermoplastic resin, and the photovoltaic element are stacked to form a stacked body and said stacked body is heated while degassing to closely contact and fix it.

73. The manufacturing method for the solar cell module, according to claim 52, wherein a first sheet member of a thermoplastic resin, the covering means made of the flame resistive fiber, another sheet member of a thermoplastic resin, and the photovoltaic element are stacked to form a stacked body and said stacked body is heated and pressed to closely contact and fix it.

74. A solar cell module manufacturing apparatus for manufacturing the solar cell module according to claim 30 by the manufacturing method according to claim 52.

75. An installing method for a solar cell module, comprising fixing the solar cell module to a roof substrate or an external wall by a fixing member, wherein said solar cell module is the solar cell module according to claim 30.

76. A construction comprising a solar cell module, in which the solar cell module is fixed to a trestle, a roof substrate, or an external wall by a fixing member, wherein said solar cell module is the solar cell module according to claim 30.

77. A photovoltaic power-generating apparatus comprising the solar cell module according to claim 30 and a power conversion apparatus.

78. A solar cell module comprising a photovoltaic element sealed with a filler, wherein a covering means comprising a layer made of a flame resistive fiber having flame resistive performance is provided on a non-light-receiving face side of said photovoltaic element.

79. The solar cell module according to claim 78, wherein said covering means is adhered to the non-light-receiving face side of said photovoltaic element with a filler and has a layer formed by impregnating a filler in the covering means.

80. The solar cell module according to claim 78, wherein said covering means is a carbon fiber.

81. The solar cell module according to claim 78, wherein said covering means is a mesh.

82. The solar cell module according to claim 78, wherein said covering means is a flame resistive fiber obtained from a special acrylic fiber.

83. The solar cell module according to claim 78, wherein said covering means is a felt textile.

84. The solar cell module according to claim 78, wherein an insulation film is put between said covering means and said photovoltaic element.

85. The solar cell module according to claim 78, wherein said photovoltaic element and an enclosure of the light-receiving face side of said photovoltaic element are flexible.

86. The solar cell module according to claim 78, wherein said photovoltaic element is an amorphous silicon photovoltaic element formed on a stainless steel substrate.

87. A manufacturing method for solar cell module, comprising stacking a covering means composed of a flame resistive fiber, a sheet member of a thermoplastic resin, and a photovoltaic element and heating while degassing portions between the covering means and the sheet member of the thermoplastic resin and between the sheet member of the thermoplastic resin and the photovoltaic element to closely contact each other and fix them.

88. A manufacturing method for solar cell module, comprising applying either one of an adhesive material or a sticky material to a covering means composed of a flame resistive fiber, stacking the applied covering means and a photovoltaic element, and pressing a portion between the covering means and the photovoltaic element to closely contact each other and fix them.

89. A manufacturing apparatus for solar cell module, comprising a degassing means and a heating means, wherein a covering means composed of a flame resistive fiber, a sheet member of a thermoplastic resin, and a photovoltaic element are stacked and heated while degassing portions between the covering means and the sheet member of the thermoplastic resin and between the sheet member of the thermoplastic resin and the photovoltaic element.

90. A manufacturing apparatus for solar cell module, comprising means of applying at least one of an adhesive material or a sticky material, a covering means composed of a flame resistive fiber and a heating means, wherein the photovoltaic element and the covering means are stacked, and a portion between the covering means and the photovoltaic element is pressed to closely contact each other and fix them.

91. The installing method for solar cell module, comprising fixing the solar cell module according to claim 78 to a trestle, a roof substrate, or an external wall with a fixing member.

92. A construction comprising the solar cell module according to claim 78 fixed to a roof substrate or an external wall with a fixing member.

93. A photovoltaic power-generating apparatus comprising the solar cell module according to claim 78 and a power conversion apparatus.

94. The solar cell module according to claim 78, wherein a weight of said flame resistive fiber is equal to or more than 100 g/m².
